(19) United States
(12) Patent Application Publication
(10) Pub. No.: US 2007/0165460 A1
(43) Pub. Date: Jul. 19, 2007

(54) Nonvolatile semiconductor memory device and programming or erasing method therefor

(76) Inventors: Masahiro Toki, Shiga (JP); Hiroyasu Nagai, Osaka (JP); Kenji Misumi, Kyoto (JP); Hideto Kotani, Osaka (JP)

Correspondence Address: MCDERMOTT WILL & EMERY LLP, 600 13TH STREET, N.W., WASHINGTON, DC, 20005-3096, US

(21) Appl. No.: 11/633,586

(22) Filed: Dec. 5, 2006

(30) Foreign Application Priority Data
Jan. 17, 2006 (JP) 2006-009216

(51) Int. Cl. G11C 16/04; G11C 16/06; G11C 11/34

(52) U.S. Cl. 365/185.22; 365/185.24; 365/185.18

(57) ABSTRACT

In a nonvolatile memory cell having a trap layer, by executing first charge injection with a given wait time being secured and second charge injection after the first charge injection in a programming or erasing sequence, surrounding charge that may deteriorate the data retention characteristic is reduced utilizing an initial variation (charge loss phenomenon caused by binding of injected charge with the surrounding charge in an extremely short time) occurring immediately after programming. Thereafter, the charge loss in the initial variation is compensated, so that the subsequent data retention characteristic is improved. The second charge injection is executed only when a predetermined determination level has been reached.

### BACKGROUND OF THE INVENTION

The present invention relates to an electrically programmable, erasable nonvolatile semiconductor memory device that has a trap layer inside a gate insulation film formed between a channel region and a gate electrode of each memory cell transistor, and a programming or erasing method for such a semiconductor memory device.

In a conventional nonvolatile memory having a trap layer, electric charge (electrons and holes) is trapped, by electrical charge injection, in a discrete trap layer (a SiN film or a transition region at the interface of a SiN film/a top SiO₂ film) existing inside an insulating film (SiO₂) formed between a channel region and a gate electrode of each memory cell. Data “0” or data “1” is determined with respect to the threshold voltage of the memory cell, to thereby store information.

It should be noted in the following description that injection of electrons is regarded as programming (write) while injection of holes is regarded as erasing, and that injected charge and surrounding charge in programming operation are respectively regarded as electrons and holes.

FIG. 23 is a schematic cross-sectional view of a nonvolatile memory having a trap layer, with the x-axis representing the channel direction. Using FIG. 23, the configuration and operation of the conventional nonvolatile memory having a trap layer will be described.

Referring to FIG. 23, the nonvolatile memory includes: a semiconductor substrate 3001 made of p-type silicon; a p-type channel region 3002 placed on the semiconductor substrate 3001; a first impurity region 3003 made of n-type semiconductor placed on the semiconductor substrate 3001 on one side of the channel region 3002; a second impurity region 3004 made of n-type semiconductor placed on the semiconductor substrate 3001 on the other side of the channel region 3002; a bottom insulating film 3007 made of a silicon oxide film placed on the semiconductor substrate 3001; a trap layer 3006 made of a silicon nitride/oxide film placed on the bottom insulating film 3007; a top insulating film 3005 made of a silicon oxide film placed on the trap layer 3006; and a gate electrode 3008 made of n-type polysilicon placed on the top insulating film 3005.

In programming, about 9 V is applied to the gate electrode 3008, about 5 V to the first impurity region 3003, about 1 V to the second impurity region 3004 and 0 V to the semiconductor substrate 3001. With this voltage application, part of electrons moving from the second impurity region 3004 to the first impurity region 3003 is made hot with a high electric field in the neighborhood of the first impurity region 3003 and injected locally into the trap layer 3006. This raises the memory cell threshold voltage to a high state.

In erasing, about −3 V is applied to the gate electrode 3008, about 5 V to the first impurity region 3003, and 0 V to the semiconductor substrate 3001, while the second impurity region 3004 is put in a floating state. With this voltage application, part of holes generated due to inter-band tunneling inside the first impurity region 3003 is made hot with a high electric field in the neighborhood of the first impurity region 3003 and injected locally into the trap layer 3006. This lowers the memory cell threshold voltage to a low state.

In reading, about 4 V is applied to the gate electrode 3008, 0 V to the first impurity region 3003, about 1.5 V to the second impurity region 3004, and 0 V to the semiconductor substrate 3001. With this voltage application, data “0” or “1” is obtained depending on existence/absence of charge in the trap layer 3006.

The behavior of trapped charge in a non-biased state after programming in the conventional nonvolatile memory having a trap layer will be described with reference to FIGS. 24A through 24E.

FIGS. 24A and 24B show distributions of the memory cell threshold voltage, where the x-axis represents the memory cell threshold voltage and the y-axis represents the number of memory cells to be programmed. FIGS. 24C through 24E show probability density distributions in the neighborhood of the first impurity region 3003, where the x-axis represents the distance in the direction of arrow x in FIG. 23 and the y-axis represents the charge density.

FIG. 24A shows a distribution 3101 of the memory cell threshold voltage observed immediately after programming. FIG. 24B shows a distribution 3102 of the memory cell threshold voltage in the last period of life. The reference numeral 3103 denotes a verify level. FIG. 24C shows a probability density distribution 3111 of electrons injected under programming and a probability density distribution 3112 of holes injected under erasing preceding the programming. FIG. 24D shows a probability density distribution 3121 of electrons after binding with holes, and a probability density distribution 3122 of holes after binding with electrons. FIG. 24E shows a probability density distribution 3131 of electrons in the last period of life.

In the state described above in which two types of charge are locally trapped, in the distribution 3101 of the memory cell threshold voltage observed immediately after programming, electrons and holes exhibit different probability density distributions 3111 and 3112 from each other as shown in FIG. 24C. In the overlap portion of the probability density distributions 3111 and 3112 of electrons and holes, electrons and holes are bound together instantaneously, to exhibit the probability density distribution 3121 of electrons and the probability density distribution 3122 of holes as shown in FIG. 24D. Thereafter, the binding between electrons and holes advances with lateral diffusion of charge, causing a change in memory cell threshold voltage.

In the distribution 3102 of the memory cell threshold voltage in the last period of life, since the total number of electrons is greater than that of holes in the programming state, holes disappear, leaving only the probability density distribution 3131 of electrons behind as shown in FIG. 24E. Thus, by reducing the total number of holes after programming, the data retention characteristic of memory cells can be improved.

In U.S. Pat. No. 5,365,486, programming is executed again for a memory cell of which the threshold voltage has decreased due to a disturb and fails to satisfy a verify level, so that the memory cell threshold voltage can satisfy the verify level and be suppressed from changing.

In the conventional nonvolatile memory having a trap layer, when charge is injected locally into the trap layer, the trapped charge diffuses in the lateral direction in a non-biased state and is bound with surrounding charge, causing a change in memory cell threshold voltage. The data retention characteristic may deteriorate with this change in memory cell threshold voltage, and this will cause lower access speed and erroneous data read in the market.

The data retention characteristic has dependence on the number of times of programming or erasing: that is, as the number of times of programming or erasing is greater, the data retention characteristic will deteriorate more greatly. This blocks improvement in the guaranteed number of times of programming or erasing for products.

### SUMMARY OF THE INVENTION

An object of the present invention is suppressing deterioration of the data retention characteristic of nonvolatile semiconductor memory cells having a trap layer.

To attain the above object, according to the present invention, in programming or erasing of a nonvolatile semiconductor memory device having a trap layer, after charge injection is executed up to a predetermined threshold voltage, a given wait time is secured, and then charge injection is further executed up to a predetermined threshold voltage. The charge injection after the wait time may be omitted under given conditions.

According to the present invention, by executing first charge injection with a subsequent given wait time being secured and second charge injection after the first charge injection in a programming or erasing sequence, surrounding charge that may deteriorate the data retention characteristic is reduced utilizing an initial variation (charge loss phenomenon caused by binding of injected charge with the surrounding charge in an extremely short time period) occurring immediately after the charge injection. Thereafter, the charge loss in the initial variation is compensated, so that the subsequent data retention characteristic is improved. The second charge injection may be omitted if unnecessary, and in this case, high-speed programming or erasing is attained.

### BRIEF DESCRIPTION OF THE DRAWINGS

FIG. 1 is a view showing a programming or erasing method for a nonvolatile semiconductor memory device in Embodiment 1.

FIGS. 2A through 2H are views showing the behavior of trapped charge in the nonvolatile semiconductor memory device in Embodiment 1.

FIGS. 3A and 3B are views showing changes in the memory cell threshold voltage of the nonvolatile semiconductor memory device in Embodiment 1.

FIG. 4 is a view of memory cell threshold voltage distributions of multi-valued memory, used for description of Embodiment 1.

FIG. 5 is a view showing a circuit configuration of the nonvolatile semiconductor memory device in Embodiment 1.

FIG. 6 is a view showing a programming or erasing method for a nonvolatile semiconductor memory device in Embodiment 2.

FIGS. 7A through 7F are views showing the behavior of trapped charge in the nonvolatile semiconductor memory device in Embodiment 2.

FIG. 8 is a view showing a programming or erasing method for a nonvolatile semiconductor memory device in Embodiment 3.

FIG. 9 is a view showing a programming or erasing method for a nonvolatile semiconductor memory device in Embodiment 4.

FIG. 10 is a view showing a programming or erasing method for a nonvolatile semiconductor memory device in Embodiment 5.

FIG. 11 is a view showing an alternative method in Embodiment 5.

FIG. 12 is a view showing another alternative method in Embodiment 5.

FIG. 13 is a view showing a circuit configuration of the nonvolatile semiconductor memory device in Embodiment 5.

FIG. 14 is a view showing a programming or erasing method for a nonvolatile semiconductor memory device in Embodiment 6.

FIG. 15 is a view showing a programming or erasing method for a nonvolatile semiconductor memory device in Embodiment 7.

FIG. 16 is a view showing a circuit configuration of the nonvolatile semiconductor memory device in Embodiment 7.

FIG. 17 is a view showing a circuit configuration of electronic equipment using the nonvolatile semiconductor memory device in Embodiment 7.

FIG. 18 is a view showing a programming or erasing method for a nonvolatile semiconductor memory device in Embodiment 8.

FIG. 19 is a view of memory cell threshold voltage distributions of multi-valued memory, used for description of Embodiment 9.

FIG. 20 is a view showing a programming or erasing method for a nonvolatile semiconductor memory device in Embodiment 9.

FIG. 21 is a view showing an alternative method in Embodiment 9.

FIG. 22 is a view showing a programming or erasing method for a nonvolatile semiconductor memory device in Embodiment 10.

FIG. 23 is a view showing a memory cell structure of a conventional nonvolatile semiconductor memory device.

FIGS. 24A through 24E are views showing the behavior of trapped charge in the conventional nonvolatile semiconductor memory device.

### DESCRIPTION OF THE PREFERRED EMBODIMENTS

Hereinafter, preferred embodiments of the present invention will be described with reference to the accompanying drawings. Note that each memory cell of the nonvolatile semiconductor memory devices in all the embodiments to be described hereinafter has a trap layer.

It should be noted in the following description that the “first charge injection” includes first programming and a wait time and the “second charge injection” includes second programming.

### Embodiment 1

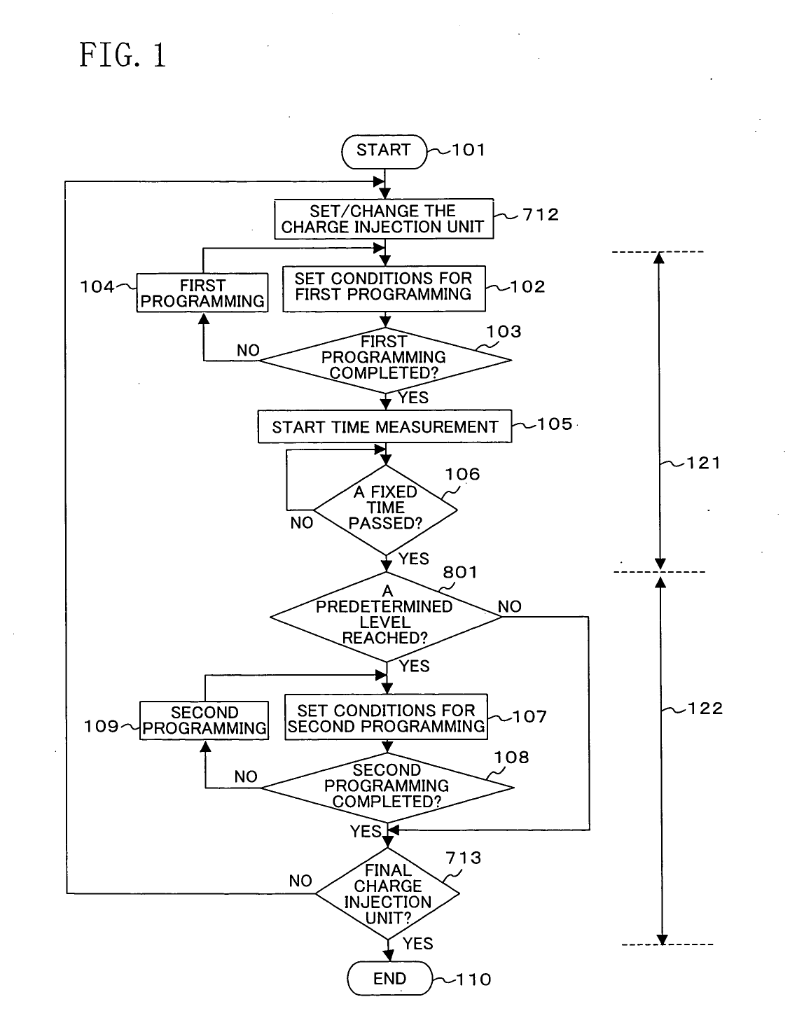

FIG. 1 is a flowchart of a programming or erasing method for a nonvolatile semiconductor memory device in Embodiment 1 of the present invention. Hereinafter, a method adopted when programming is made for a given nonvolatile memory cell will be described.

In the flowchart of FIG. 1, blocks 101 and 110 respectively represent the start and the end, 102, 104, 105, 107 and 109 represent processing, and 103, 106 and 108 represent decision. The reference numerals 121 and 122 represent ranges. There are also block 712 representing processing and blocks 801 and 713 representing decision, which will be described in a later stage.

The block 102 represents processing of setting conditions for executing the first programming, 104 represents processing of executing the first programming, and 105 represents processing of starting time measurement. The block 107 represents processing of setting conditions for executing the second programming, and 109 represents processing of executing the second programming. The block 103 represents decision on whether or not the first programming has been completed, 106 represents decision on whether or not a fixed time has passed, and 108 represents decision on whether or not the second programming has been completed. The range 121 covers the first charge injection, and the range 122 covers the second charge injection.

The programming flow for a given memory cell, starting at the start 101, proceeds to the processing 102 of setting desired first programming conditions and then to the decision 103 on whether or not the first programming has been completed. The processing 102 includes, for example, setting the voltage condition, pulse width condition and the like in programming. The decision 103 includes, for example, programming verify of verifying that the programming has been made up to a predetermined threshold voltage.

If it is decided in the decision 103 that the first programming has not been completed, the flow proceeds to the first programming processing 104. After execution of the first programming processing 104, the flow returns to the decision 103 on whether or not the first programming has been completed via the processing 102 of setting desired first programming conditions. The processing blocks 104 and 102 are repeated until completion of the first programming is verified in the decision 103.

If it is decided in the decision 103 that the first programming has been completed, the processing 105 of starting time measurement is executed, and the flow proceeds to the decision 106. In the decision 106, whether or not a fixed time has passed from the start of the measurement in the processing 105 is checked. If the fixed time has passed, the flow proceeds to the processing 107 of setting conditions for executing the second programming. If the fixed time has not passed, the decision 106 is repeated until the condition for the decision 106 is satisfied. A longer time is more desirable as the fixed time in the decision 106. The series of processing and decision described above fall in the range 121 of the first charge injection, which is composed of the first programming and the wait time determined by the fixed time. The subsequent series of processing and decision fall in the range 122 of the second charge injection.

After the processing 107 of setting conditions for executing the second programming, the flow proceeds to the decision 108 on whether or not the second programming has been completed. The processing 107 includes, for example, setting the voltage condition, pulse width condition and the like in programming. The decision 108 includes, for example, verifying that a programming pulse has been applied a predetermined number of times.

If it is decided in the decision 108 that the second programming has not been completed, the flow proceeds to the second programming processing 109. After execution of the second programming processing 109, the flow returns to the decision 108 on whether or not the second programming has been completed via the processing 107 of setting desired second programming conditions. The processing blocks 109 and 107 are repeated until completion of the programming is determined in the decision 108. If it is determined in the decision 108 that the second programming has been completed, the flow proceeds to the end 110 to terminate the series of programming operations.

The programming flow described above is also applicable to programming of a memory cell array by executing each of the processing blocks in programming units such as addresses.

In the flow chart of FIG. 1, the block 713 represents decision on whether or not the current programming unit is the final one in a given programming area of the memory cell array, and 712 represents processing of setting or changing the programming unit.

Before execution of the first programming, the processing 712 of setting the programming unit for which the programming is to be executed is performed. The first and second programming operations are then executed in the manner described above. If completion of the programming is verified in the decision 108 on whether or not the second programming has been completed, the flow proceeds to the decision 713 to decide whether or not the current programming unit is the final one in a given programming area of the memory cell array. If it is decided in the decision 713 that the current programming unit is not the final one, the flow proceeds to the processing 712 to change the programming unit before executing the first programming. If it is decided in the decision 713 that the current programming unit is the final one, the flow proceeds to the end 110 to terminate the series of programming operations. The programming unit as used herein refers to an address, for example, and the change of the programming unit refers to increment of the address, for example. Note that the second programming may be repeated any given number of times.

In the flowchart of FIG. 1, the block 801 represents decision on whether or not a predetermined determination level has been reached. The predetermined determination level as used herein refers to the verify level used in the first programming, a level obtained by adding a variation expectation in the wait time to the verify level, or the like.

If the predetermined level has been reached, the flow proceeds to the processing 107 of setting second programming conditions, to execute the second charge injection in the manner described above. If the predetermined level has not been reached, the flow proceeds to the decision 713 on whether or not the current programming unit is the final one for the charge injection, and then proceeds to the first programming for another programming unit if the current programming unit is not the final one, or to the end 110 if it is the final one.

Depending on the decision 801 on whether or not a predetermined level has been reached, the second charge injection is omitted if the amount of charge of the memory cell threshold voltage with binding between electrons and holes during the first programming and the wait time is small. Therefore, by setting a programming level securing a necessary margin from a read level, for example, as the predetermined determination level, the second programming can be executed only for memory cells that have reached the determination level. Thus, the effect of the present invention can be obtained with a more optimized time.

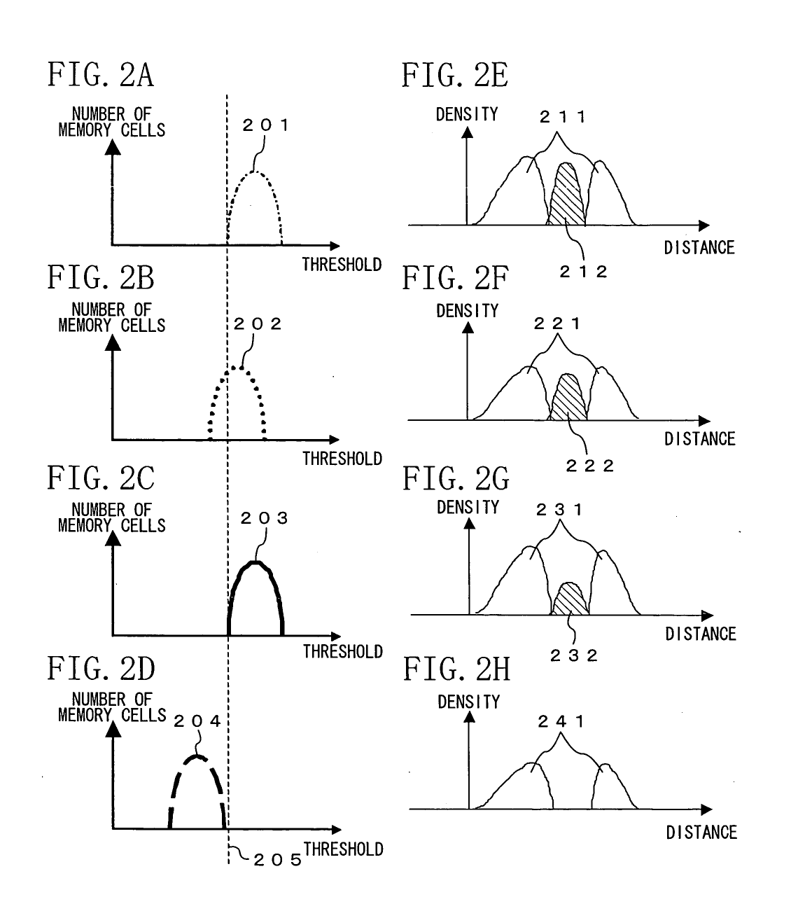

The behavior of charge in Embodiment 1 of the present invention will be described with reference to FIGS. 2A through 2H. FIGS. 2A through 2H show the behavior of trapped charge in a nonvolatile memory having a trap layer, which is observed when the programming flow described above with reference to FIG. 1 is executed for a memory cell array.

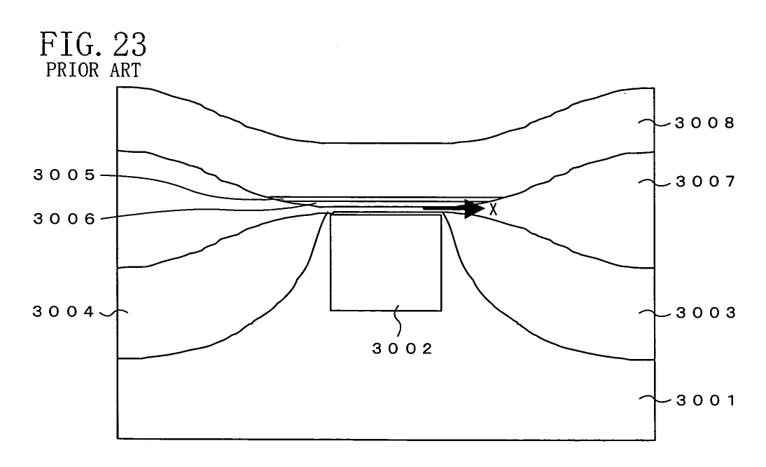

FIGS. 2A through 2D show distributions of the memory cell threshold voltage, where the x-axis represents the memory cell threshold voltage and the y-axis represents the number of memory cells to be programmed. FIGS. 2E through 2H show probability density distributions in the neighborhood of the first impurity region 3003 in a memory cell shown in FIG. 23, where the x-axis represents the distance in the direction of arrow x in FIG. 23 and the y-axis represents the charge density.

FIG. 2A shows a distribution 201 of the memory cell threshold voltage observed immediately after the first programming. FIG. 2B shows a distribution 202 of the memory cell threshold voltage observed after the lapse of a fixed time. FIG. 2C shows a distribution 203 of the memory cell threshold voltage observed immediately after execution of the second programming after the lapse of the fixed time. FIG. 2D shows a distribution 204 of the memory cell threshold voltage observed in the last period of life. In FIGS. 2A through 2D, the reference numeral 205 represents a programming verify level.

FIG. 2E shows a probability density distribution 211 of electrons injected under the first programming and a probability density distribution 212 of holes injected under erasing preceding the first programming. FIG. 2F shows a probability density distribution 221 of electrons after binding with holes and a probability density distribution 222 of holes after binding with electrons. FIG. 2G shows a probability density distribution 231 of electrons injected under the second programming after the binding with holes and a probability density distribution 232 of holes after the binding with electrons. FIG. 2H shows a probability density distribution 241 of electrons in the last period of life.

In the distribution 201 of the memory cell threshold voltage observed immediately after completion of the first programming, electrons and holes exhibit different probability density distributions from each other as shown in FIG. 2E. In their overlap portions, electrons and holes are bound together instantaneously. After the lapse of a fixed time from the completion of the first programming, the probability density distribution 221 of electrons and the probability density distribution 222 of holes are as shown in FIG. 2F, and the distribution of the memory cell threshold voltage falls from 201 to 202.

Thereafter, once the second programming is executed, the distribution of the memory cell threshold voltage rises from 202 to the distribution 203 that is observed immediately after completion of the second programming as shown in FIG. 2C. At this time, that is, immediately after completion of the second programming, electrons and holes exhibit the probability density distribution 231 of electrons and the probability density distribution 232 of holes as shown in FIG. 2G. That is, the probability density of holes that may deteriorate the data retention characteristic of memory cells has decreased while the probability density of electrons has increased.

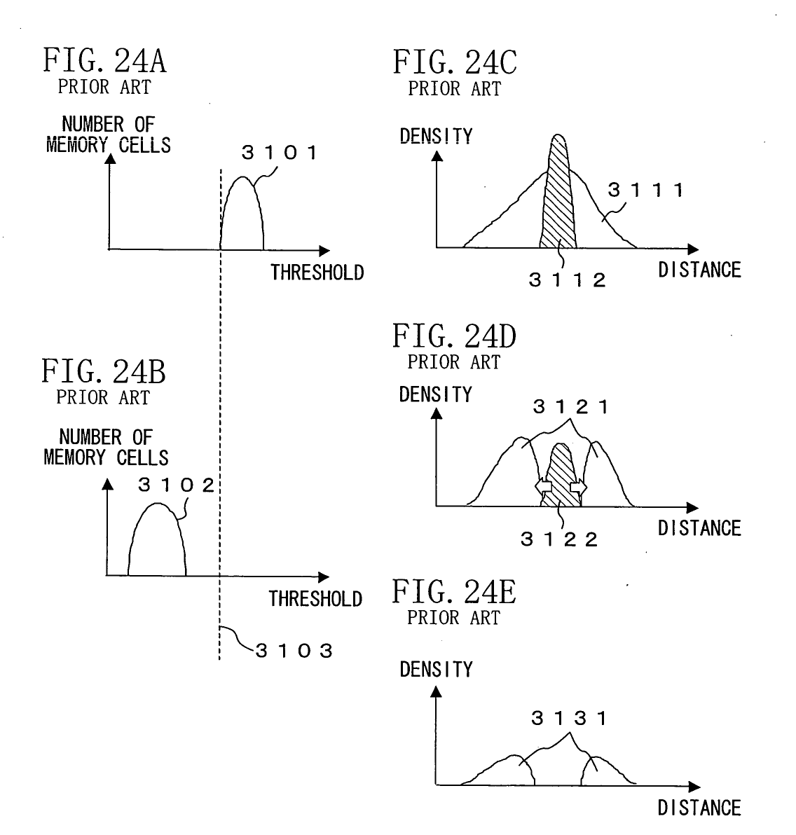

As a result, as an effect of the present invention, subsequent binding between electrons and holes with lateral diffusion of charge is suppressed compared with the conventional case shown in FIGS. 24A through 24E. This reduces the amount of change of the memory cell threshold voltage with time and improves the data retention characteristic of the memory cells. That is, in the distribution 204 of the memory cell threshold voltage observed in the last period of life as shown in FIG. 2D, the probability density distribution 241 of electrons is high as shown in FIG. 2H compared with the conventional probability density distribution 3131 of electrons shown in FIG. 24E.

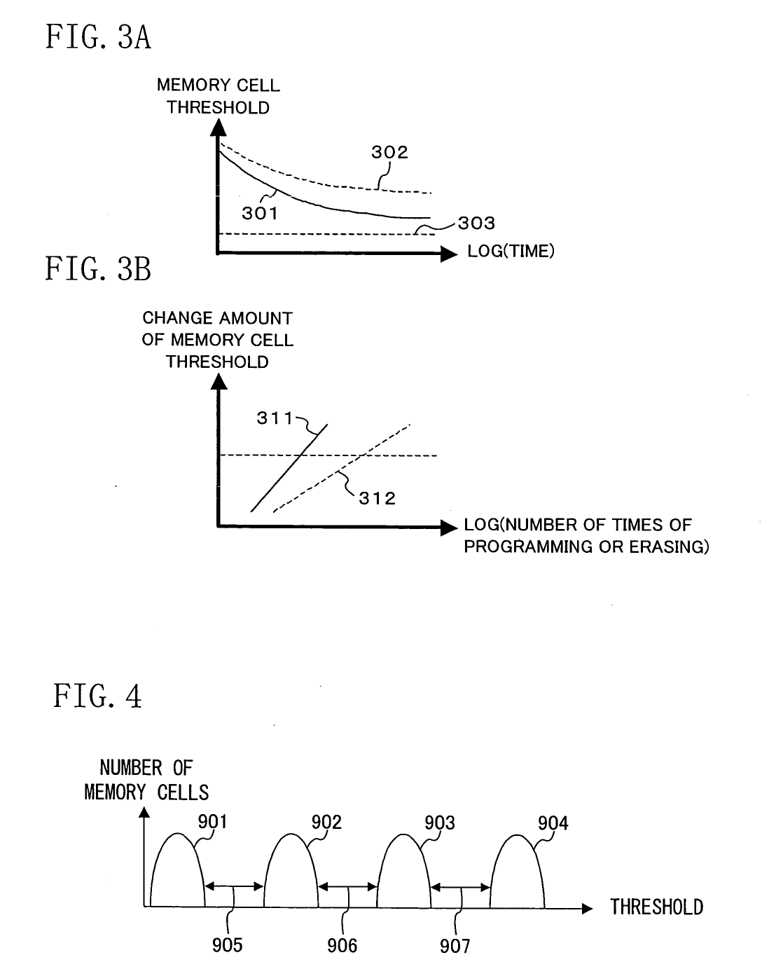

FIGS. 3A and 3B show changes in memory cell threshold voltage observed when the present invention is applied. In FIG. 3A, in which the x-axis represents the holding time and the y-axis represents the memory cell threshold voltage, lines 301 and 302 represent changes in memory cell threshold voltage in the conventional case and according to the present invention, respectively, and 303 represents a read level. The memory cell threshold voltage 302 according to the present invention is higher than the conventional memory cell threshold voltage 301 at every holding time. This indicates that a larger margin can be secured for data read and thus the data retention characteristic improves according to the present invention.

In FIG. 3B, in which the x-axis represents the number of times of programming or erasing and the y-axis represents the change amount of the memory cell threshold voltage, lines 311 and 312 represent the dependence of the threshold change amount on the number of times of programming or erasing in the conventional case and according to the present invention, respectively. According to the present invention, the number of times of programming or erasing that gives the same change amount of the memory cell threshold voltage is large compared with the conventional case.

In this embodiment, a further effect will be obtained by executing the second programming in smaller units of the voltage and the pulse width, for example.

The above effect of this embodiment will be described with reference to FIG. 4, which is a view of memory cell threshold voltage distributions in a multi-valued memory. The reference numerals 901 through 904 respectively denote distributions of the memory cell threshold voltage for data in the first, second, third and fourth levels in the multi-valued memory, and 905 through 907 respectively denote threshold voltage margins required for discrimination between the first data and the second data, between the second data and the third data, and between the third data and the fourth data.

The effect will be described using specifically an intermediate threshold voltage level. For example, the distribution 902 of the memory cell threshold voltage for data in the second level will be taken. If a predetermined level has been reached after the first programming, the second programming is performed up to a predetermined level. At this time, by executing the programming in smaller units of the voltage and the pulse width, the upward rise of the distribution 902 of the memory cell threshold voltage for data in the second level can be minimized. This in turn can reduce the threshold voltage margin 906 required for discrimination between the second data and the third data. As a result, a multi-valued memory having more levels can be achieved. Otherwise, with reduction of the threshold levels as a whole, a booster circuit can be scaled down.

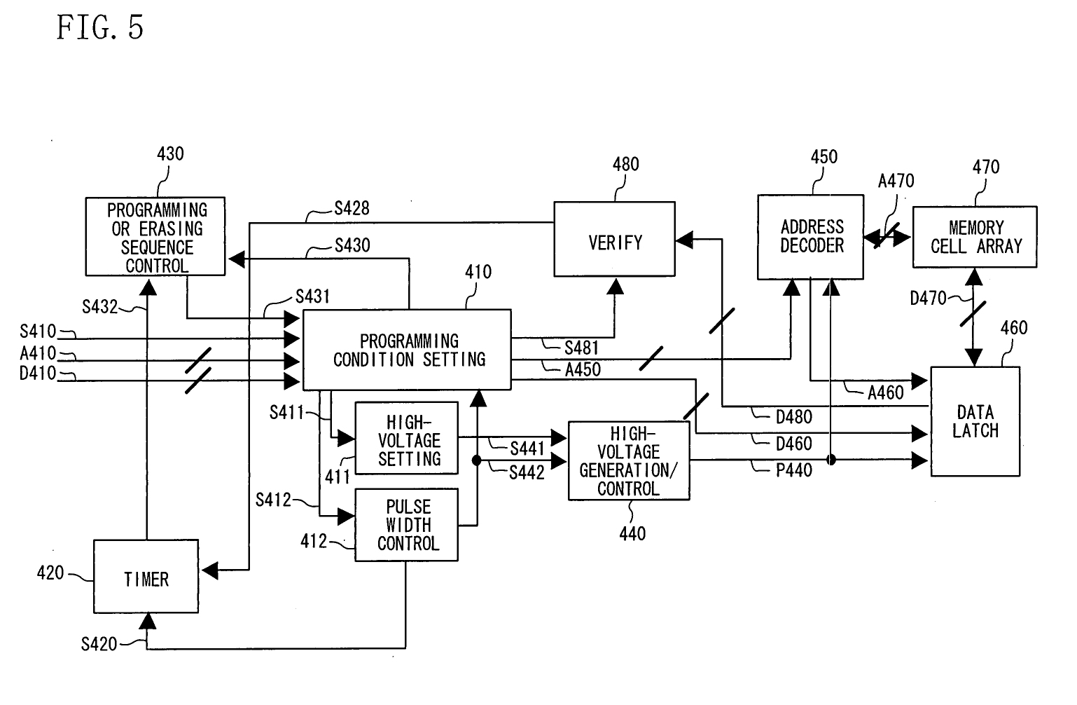

Embodiment 1 can be implemented with the configuration of FIG. 5. FIG. 5 shows a nonvolatile semiconductor memory device in Embodiment 1 of the present invention. Referring to FIG. 5, a method adopted when programming is made for a nonvolatile memory cell at a given address will be described.

The nonvolatile semiconductor memory device of FIG. 5 includes a programming condition setting circuit 410, a high-voltage setting circuit 411, a pulse width control circuit 412, a timer circuit 420, a programming or erasing sequence control circuit 430, a high-voltage generation/control circuit 440, an address decoder circuit 450, a data latch circuit 460, a memory cell array 470 and a verify circuit 480.

In FIG. 5, also shown are control signals S410 to S412, S420, S428, S430 to S432, S441, S442 and S481, address buses A410, A450, A460 and A470, data buses D410, D460 D470 and D480 and a high-voltage signal P440.

First, the first programming operation will be described. The programming condition setting circuit 410 receives the control signal S410, the programming address A410 and the programming data D410 input externally and sets first programming conditions. Note herein that the control signal is a programming command or the like, and the programming conditions include the voltage condition, the pulse width condition and the like in programming. According to the input setting conditions, the voltage condition and the pulse width condition are sent to the high-voltage setting circuit 411 and the pulse width control circuit 412, respectively, for setting and/or control. The high voltage required for programming is controlled with the high-voltage generation/control circuit 440 based on the set value in the high-voltage setting circuit 411, and is output as the high-voltage signal P440. The high-voltage signal P440 is input into the address decoder circuit 450 and the data latch circuit 460, to be applied to a memory cell in the memory cell array 470 selected with the address decoder circuit 450 based on data from the data latch circuit 460 for the time period set in the pulse width control circuit 412.

Termination of the programming is decided under programming verify performed by the verify circuit 480 that verifies that the programming has been made up to a predetermined threshold level.

If it is decided under the programming verify that the first programming has not yet been completed, a first programming pulse is applied. After the application of the first programming pulse, desired first programming conditions are set, and then the programming verify on whether or not the first programming has been completed is performed. The application of the first programming pulse is repeated until completion of the programming is decided under the programming verify.

If completion of the programming is decided under the programming verify, time measurement is started in the timer circuit 420 with the signal S428 output from the verify circuit 480 to the timer circuit 420. After the lapse of a fixed time, the control signal S432 is output to the programming or erasing sequence control circuit 430, with which the second programming operation is started.

Alternatively, in the case of a programming flow involving no verify operation, the timer circuit 420 starts the time measurement with the signal S420 indicating timing of termination of the pulse application output from the pulse width control circuit 412. After the lapse of a fixed time, the control signal S432 is output to the programming or erasing sequence control circuit 430, with which the second programming operation is started.

Next, the second programming operation will be described. The programming condition setting circuit 410 starts the second programming operation with the control signal S431 sent from the programming or erasing sequence control circuit 430, and sets second programming conditions. The programming conditions include the voltage condition, the pulse width condition and the like in programming, for example. According to the input setting conditions, the voltage condition and the pulse width condition are supplied to the high-voltage setting circuit 411 and the pulse width control circuit 412, respectively, for setting and/or control. The high voltage required for programming is controlled with the high-voltage generation/control circuit 440 based on the set value in the high-voltage setting circuit 411, and is output as the high-voltage signal P440. The high-voltage signal P440 is input into the address decoder circuit 450 and the data latch circuit 460, to be applied to a memory cell in the memory cell array 470 selected with the address decoder circuit 450 based on data from the data latch circuit 460 for the time period set in the pulse width control circuit 412. Termination of the programming is decided under programming verify performed by the verify circuit 480 that verifies that the programming has been made up to a predetermined threshold level.

If it is decided under the programming verify that the second programming has not yet been completed, a second programming pulse is applied. After the application of the second programming pulse, desired second programming conditions are set, and then the programming verify on whether or not the second programming has been completed is performed. The application of the second programming pulse is repeated until completion of the programming is decided under the programming verify.

If completion of the programming is decided under the programming verify, the series of programming operations is terminated.

As described above, according to the present invention, surrounding charge that may deteriorate the data detention characteristic is reduced utilizing an initial charge variation that is a charge loss phenomenon caused by the binding between injected charge and the surrounding charge occurring in an extremely short time period immediately after the charge injection. Thereafter, the charge loss in the initial variation is compensated, so that the data retention characteristic is improved after that.

The first programming (first charge injection) may be repeated a predetermined number of times. By repeating the first programming and the binding between electrons and holes occurring by leaving them to stand for a fixed time, the data retention characteristic will be further improved, and moreover the range of the distribution of the memory cell threshold voltage will advantageously be narrowed.

### Embodiment 2

In general programming or erasing of a nonvolatile memory, in many cases, all of data in a programming or erasing area is once changed to “0” data before the data in this area is erased. If cells having “1” data are erased, they will be in a deeper erase level and this may cause a leak and the like that may worsen the characteristics. The above way of erasing is adopted to prevent such an occurrence.

The present invention is also applicable to this pre-erase programming, which will be described as Embodiment 2 as follows.

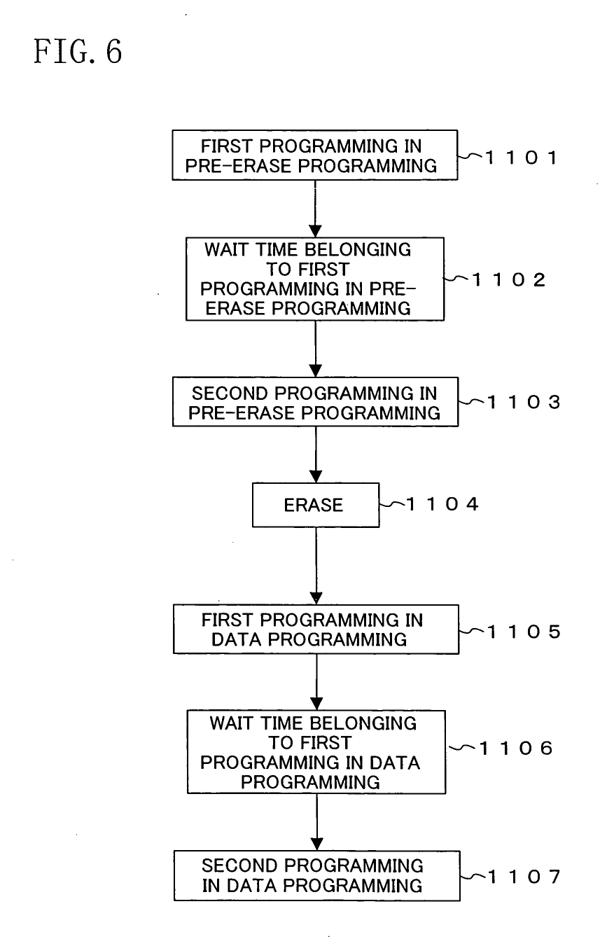

FIG. 6 is a flowchart observed when the present invention is applied to general programming or erasing of a nonvolatile memory. In FIG. 6, blocks 1101 through 1103 show a flow of pre-erase programming, and blocks 1105 through 1107 show a flow of data programming. Block 1104 represents erase of data. The blocks 1101 and 1105 represent the first programming described above, 1102 and 1106 represent the wait time described above that belongs to the first programming, and 1103 and 1107 represent the second programming described above. The second programming 1103 preceding the data erase 1104 may be omitted.

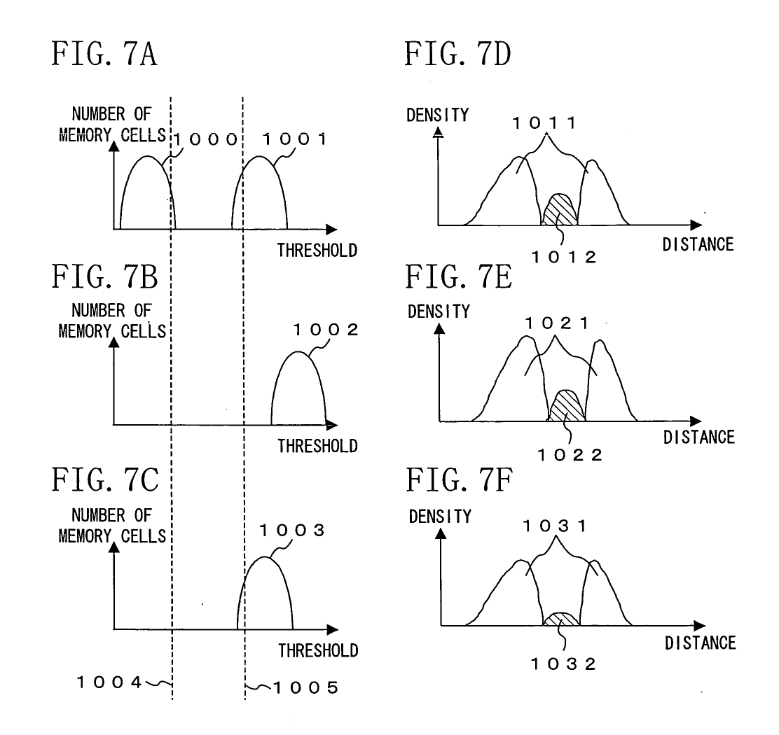

FIGS. 7A through 7F show distributions of the memory cell threshold voltage and probability density distributions, which are given to describe a programming or easing method for a nonvolatile semiconductor memory device in Embodiment 2 of the present invention.

FIGS. 7A through 7C show distributions of the memory cell threshold voltage, where the x-axis represents the memory cell threshold voltage and the y-axis represents the number of memory cells to be programmed. The reference numeral 1004 denotes an erase verify level and 1005 denotes a programming verify level. FIGS. 7D through 7F show probability density distributions in the neighborhood of the first impurity region 3003 in FIG. 23, where the x-axis represents the distance in the direction of arrow x in FIG. 23 and the y-axis represents the density.

FIG. 7A shows distributions 1000 and 1001 of the memory cell threshold voltage for data “1” and data “0”, respectively, observed immediately before pre-erase programming. FIG. 7B shows a distribution 1002 of the memory cell threshold voltage observed immediately after the first programming in the pre-erase programming. FIG. 7C shows a distribution 1003 of the memory cell threshold voltage observed in the lapse of a fixed time after the first programming in the pre-erase programming. FIG. 7D shows a probability density distribution 1011 of electrons and a probability density distribution 1012 of holes, both for data “0” observed immediately before the pre-erase programming. FIG. 7E shows a probability density distribution 1021 of electrons and a probability density distribution 1022 of holes, both observed immediately after the first programming in the pre-erase programming. FIG. 7F shows a probability density distribution 1031 of electrons and a probability density distribution 1032 of holes, both observed in the lapse of a fixed time after the first programming in the pre-erase programming.

Embodiment 2 of the present invention has features that the first programming 1101 in the pre-erase programming is performed up to a threshold voltage higher than the programming level in the data programming, and that the second programming 1103 in the pre-erase programming is not executed.

In the pre-erase programming, by executing the first programming 1101 up to a threshold voltage higher than the programming level in the data programming, the probability density distribution 1021 of electrons increases. Resultantly, the probability density distribution 1032 of hole that may deteriorate the data retention characteristic of memory cells decreases with binding between electrons and holes, while the probability density 1031 of electrons increases. Since the erase step 1104 follows the pre-erase programming without fail, the high programming level that is disadvantageous for data retention will not cause a problem. Also, since it is unnecessary to raise the level that falls with binding between electrons and holes, the second programming 1103 in the pre-erase programming can be omitted.

By lowering the probability density distribution of holes every time programming or erasing is made, the amount of holes accumulated by multiple times of programming or erasing can be kept to a minimum. This can improve the dependence of the charge retention characteristic of the nonvolatile memory on the number of times of programming or erasing, and thus high endurance can be attained.

The conditions for the first programming and the second programming may be changed every production unit or every programming or erasing unit. The production unit as used herein includes units based on the production plant and the production time, and units such as lots and wafers in which a variation occurring during production may cause a variation in the characteristics of products, for example. The programming or erasing unit as used herein includes units such as individual chips and areas, addresses and individual memory cells in which a difference in position or circuit may cause a difference in the characteristics of products, for example.

By changing the conditions as described above, optimum first and second programming can be executed irrespective of existence of a variation in characteristics with the production, circuit, position and the like.

By optimizing the programming conditions with the smallest programming or erasing unit, the greatest effect of the present invention can be obtained. By optimizing the programming conditions with a production unit or with a large or intermediate programming or erasing unit, it is possible to deal with various types of variations while minimizing the increase of the programming or erasing time, to thereby improve the effect of the present invention.

### Embodiment 3

In Embodiment 3, programming characteristics and the like of each chip are measured at the time of testing, the first and second programming conditions for programming or erasing are determined according to the measurement results, set values of the programming conditions are stored, and in actual use, programming or erasing is executed using the set values.

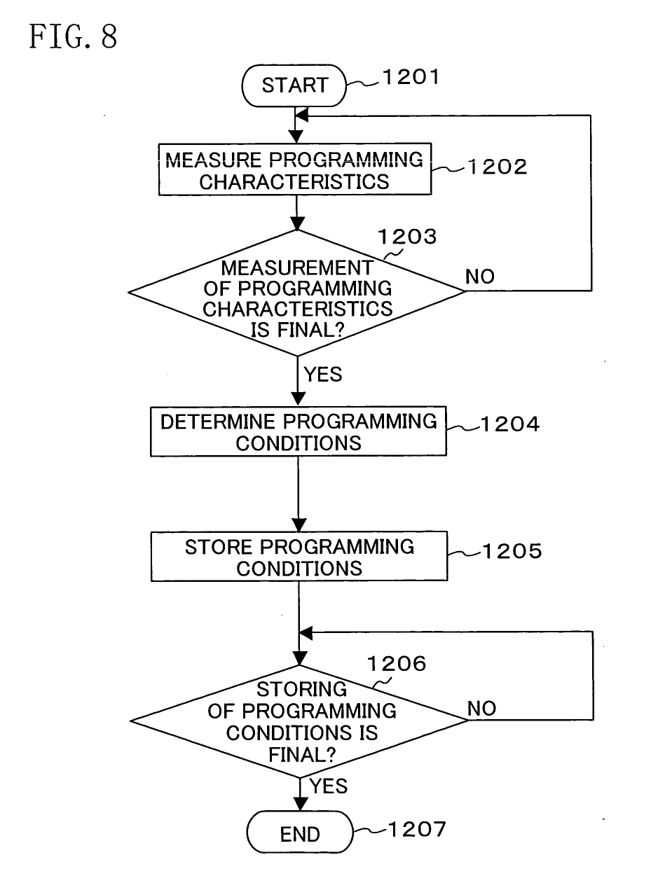

FIG. 8 is a flowchart adopted when this embodiment is applied to a testing process. In the flowchart of FIG. 8, blocks 1201 and 1207 respectively represent the start and end of the flow, 1202, 1204 and 1205 represent processing, and 1203 and 1206 represent decision.

From the start 1201, the flow proceeds to the processing 1202 of measuring programming characteristics. The characteristics to be measured include, for example, the programming threshold voltage level obtained after application of a programming pulse a predetermined number of times, the number of pulses applied or the time required until reaching a predetermined programming verify level, and the like. After the processing 1202, the decision 1203 on whether or not the measurement of the programming characteristics is final is made. If the measurement is final, the flow proceeds to the processing 1204 of determining programming conditions. If it is not final, the flow returns to the processing 1202 of measuring the programming characteristics. The processing 1204 of determining programming conditions includes, for example, calculating programming conditions from the average, maximum, minimum and the like of the characteristics within a range in which the measurement was done, in consideration of past evaluation results and the like.

After the processing 1204 of determining programming conditions, the processing 1205 of storing the programming conditions is performed. The programming conditions are stored in a nonvolatile memory, for example. After the processing 1205 of storing the programming conditions, the decision 1206 on whether or not the storing of the programming conditions is final is done. Once the storing is completed, the flow is terminated at the end 1207.

Thus, by using values reflecting the actual measurement results of characteristics of chips as the programming conditions, optimum first and second programming operations considering characteristics of each chip can be achieved. Accordingly, in actual programming or erasing, the effect of the present invention can be further enhanced without increasing the programming or erasing time.

### Embodiment 4

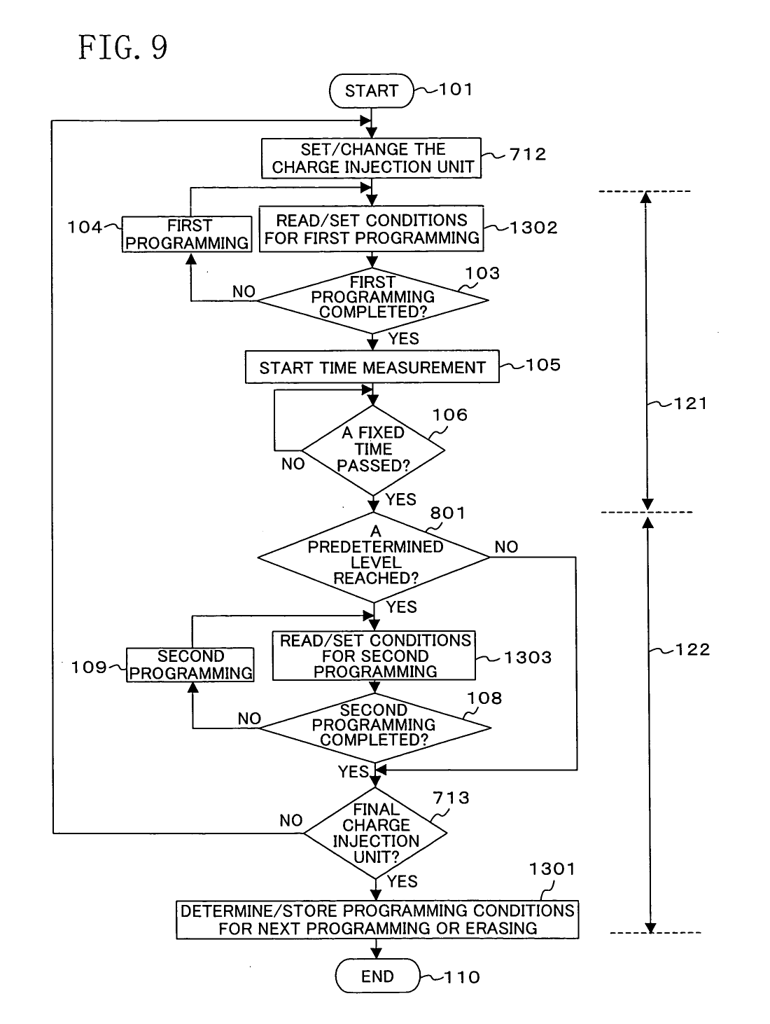

FIG. 9 is a flowchart showing a programming or erasing method for a nonvolatile semiconductor memory device in Embodiment 4 of the present invention. In the flowchart of FIG. 9, blocks 1301, 1302 and 1303 represent processing.

In the decision 713 on whether or not the current programming unit is the final one for charge injection, if it is the final one, the flow proceeds to the processing 1301 of determining and storing programming conditions for next programming or erasing, and then to the end 110. The processing 1301 of determining and storing programming conditions for next programming or erasing is processing of calculating/determining programming conditions from the average, maximum, minimum and the like of the characteristics in each charge injection unit in consideration of past evaluation results and the like, based on the programming threshold voltage level after the application of a programming pulse a predetermined number of times, the number of pulses applied or the time required until reaching a predetermined programming verify level and the like, for example, obtained in the actual execution of programming in the first charge injection 121 and the second charge injection 122. The determined programming conditions are stored in a volatile memory, a nonvolatile memory or the like.

In the next programming or erasing, in the first charge injection, the flow proceeds from the processing 712 of setting or changing the charge injection unit to the processing 1302 of reading and setting the first programming conditions. In the processing 1302, the conditions determined and stored in the processing 1301 in the last programming or erasing are used. Likewise, the second charge injection starts from the processing 1303 of reading and setting the second programming conditions, in which, also, the conditions determined and stored in the processing 1301 in the last programming or erasing are used.

By following the above flow, optimization of the first and second charge injection can be made for each memory cell as the smallest unit, and thus every memory cell can uniformly benefit from the effect of the present invention. Also, by executing the processing 1301 of determining/storing the programming conditions for next programming or erasing every programming or erasing, it is possible to execute the first and second charge injection while dealing with a variation in characteristics with the number of times of programming or erasing and the like.

### Embodiment 5

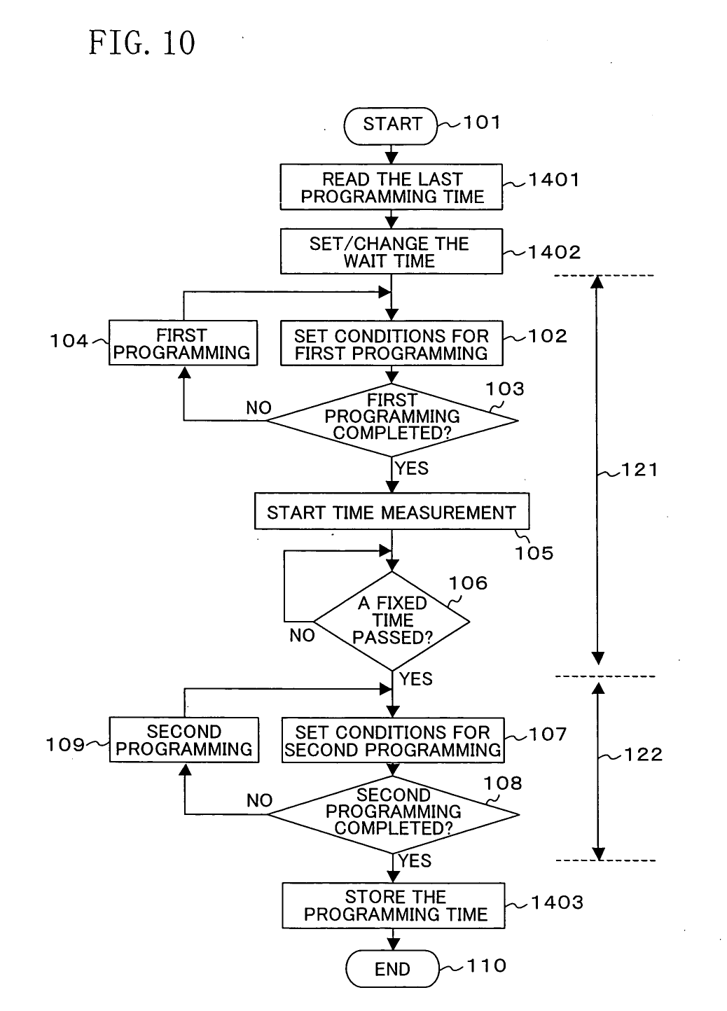

FIG. 10 is a flowchart showing a programming or erasing method for a nonvolatile semiconductor memory device in Embodiment 5 of the present invention. In the flowchart of FIG. 10, blocks 1401, 1402 and 1403 represent processing. The block 1401 represents processing of reading the last programming time, 1402 represents processing of changing the setting of the wait time, and 1403 represents processing of storing the programming time.

The programming flow for a given memory cell, starting at the start 101, proceeds to the processing 102 of setting desired first programming conditions via the processing 1401 of reading the last programming time and then the processing 1402 of changing the setting of the wait time. The processing 1401 includes, for example, reading the time at which the last programming was executed from a given area of a nonvolatile memory in which the information is stored. The processing 1402 includes, for example, shortening the setting of the fixed time used in the decision 106 if the time having passed from the last programming time is long. When the time from the last programming time is long, the binding between electrons injected for programming and holes injected for erasing must have been made sufficiently. Thus, the fixed time set in the decision 106 can be shortened, and this can shorten the programming time. On the contrary, if the time having passed from the last programming time is short, the fixed time set in the decision 106 is made long. When the time from the last programming time is short, the binding between electrons and holes must be insufficient. Thus, the binding between electrons and holes is promoted by making long the fixed time set in the decision 106, to improve the data retention characteristic.

If it is decided in the decision 108 that the programming is completed, the flow proceeds to the processing 1403 of storing the programming time and then to the end 110 to terminate the series of programming operations. The processing 1403 includes, for example, storing the time at which the programming was terminated in a given area of a nonvolatile memory. The stored information is used at the next programming or erasing.

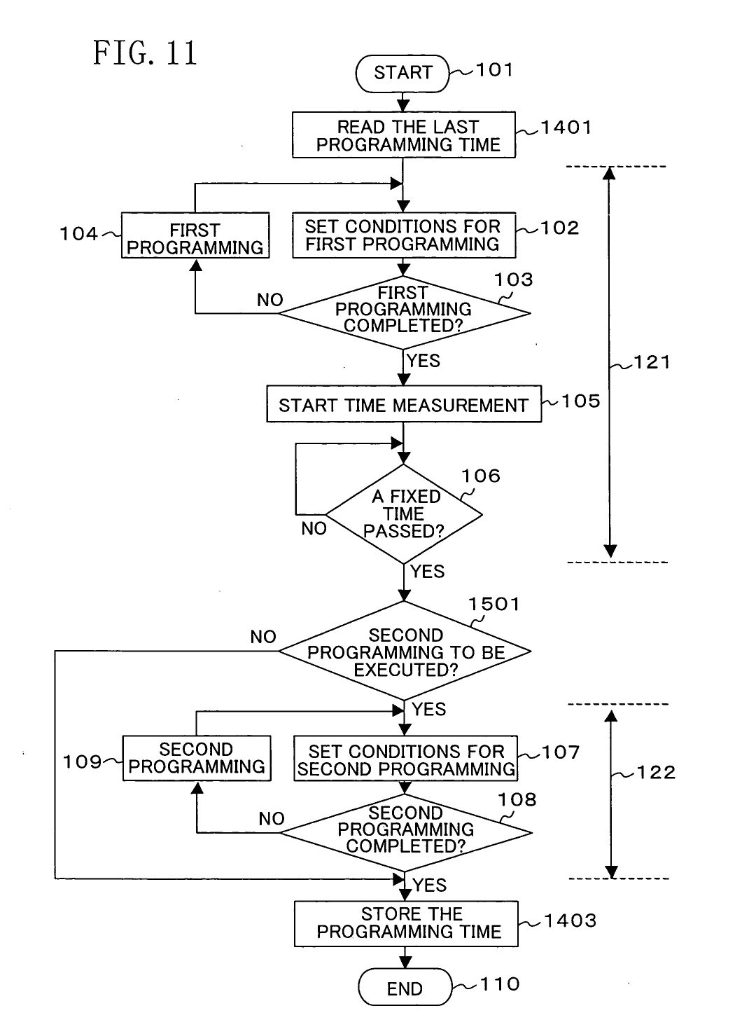

FIG. 11 is a flowchart showing an alternative method in Embodiment 5. In the flowchart of FIG. 11, block 1501 represents decision on whether or not the second programming is executed.

In the decision 106, whether or not a fixed time has passed from the start of time measurement in the processing 105 is checked. If the fixed time has passed, the flow proceeds to the decision 1501. In the decision 1501, if the time from the last programming time is long, the flow jumps to the processing 1403 of storing the programming time without executing the second programming. When the time from the last programming time is long, the binding between electrons and holes must have been made sufficiently, and thus the charge loss in the initial variation after the first programming must be small. No second programming is therefore necessary, and this can shorten the programming time. On the contrary, if the time from the last programming time is short, the flow proceeds to the processing 107 of setting the conditions for executing the second programming. When the time from the last programming time is short, the binding between electrons and holes must be insufficient, and thus the charge loss in the initial variation after the first programming must be great. The second programming is therefore executed, to improve the data retention characteristic.

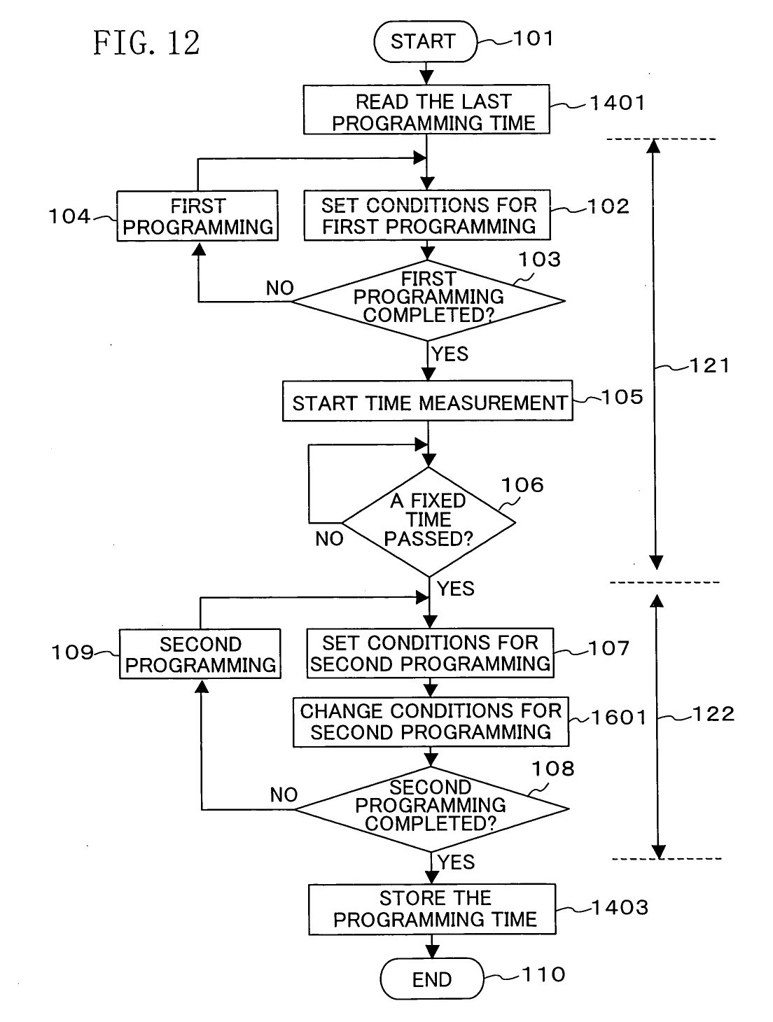

FIG. 12 is a flowchart showing another alternative method in Embodiment 5. In the flowchart of FIG. 12, block 1601 represents processing of changing the conditions for executing the second programming.

After the processing 107 of setting conditions for executing the second programming, the flow proceeds to the processing 1601 of changing the conditions for executing the second programming. The processing 107 includes, for example, setting the voltage condition, pulse width condition and the like in programming. The processing 1601 includes, for example, changing the voltage condition for the second programming to lower setting if the time having passed from the last programming time is long. When the time from the last programming time is long, the binding between electrons and holes must have been made sufficiently, and thus the charge loss in the initial variation after the first programming must be small. It is therefore unnecessary to execute the second programming at high voltage, and thus application of excessive stress can be avoided. On the contrary, if the time having passed from the last programming time is short, the voltage condition for the second programming is changed to high setting. When the time from the last programming time is short, the binding between electrons and holes must be insufficient, and thus the charge loss in the initial variation after the first programming must be great. Therefore, the second programming is executed at high voltage, to improve the data retention characteristic.

After the processing 1601, the flow proceeds to the decision 108 on whether or not the second programming has been completed. The decision 108 includes, for example, checking whether or not the programming pulse has been applied a predetermined number of times.

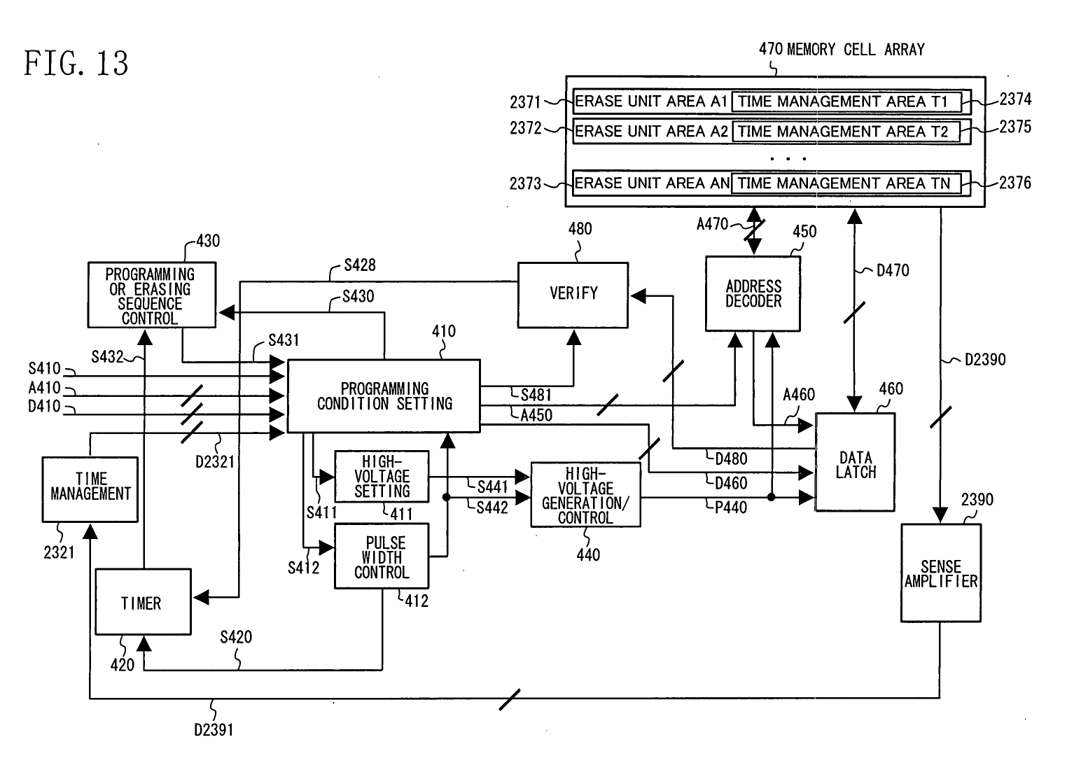

Embodiment 5 can be implemented with the configuration of FIG. 13. FIG. 13 shows a nonvolatile semiconductor memory device in Embodiment 5 of the present invention. The configuration of FIG. 13 is the same as that of FIG. 5 except for the following points. The memory cell array 470 is divided into erase unit areas A(1) 2371 to A(N) 2373, which respectively include time management areas T(1) 2374 to T(N) 2376. A time management circuit 2321 and a sense amplifier circuit 2390 are newly provided. The sense amplifier 2321 is connected with the memory cell array 470 via a data bus D2390 and with the time management circuit 2321 via a data bus D2391. The time management circuit 2321 is connected with the programming condition setting circuit 410 via a data bus D2321.

The operation in programming will be described. First, the second programming operation after the termination of the first programming operation for a given erase unit area A(1, 2, . . . , N) will be described. The current time generated in the time management circuit 2321 is set in the programming condition setting circuit 410 via the data bus D2321, and then in the data latch circuit 460 via the data bus D460. The current time data is further sent via the data bus D470 to be written in the corresponding time management area T(1, 2, . . . N) determined with the address decoder circuit 450.

Erasing operation before the first programming for a given erase unit area A(1, 2, . . . , N) will be described. Before the erasing operation, data in the corresponding time management area T(1, 2, . . . N) is read with the sense amplifier circuit 2390 via the data bus D2390. The read data, which indicates the time of the last second programming operation, is sent to the time management circuit 2321 via the data bus 2391. The time management circuit 2321 compares the time of the last second programming with the current time, calculates the elapsed wait time from the time of the last second programming until the current time, and temporarily stores the elapsed wait time information therein. The erasing operation is then performed for the erase unit area A(1, 2, . . . N) from which the time of the last second programming has been read.

The first programming operation for a given erase unit area A(1, 2, . . . , N) will then be described. The elapsed wait time information temporarily stored in the time management circuit 2321 during the erasing operation described above is set in the programming condition setting circuit 410 via the data bus D2321. The programming condition setting circuit 410 sets the first programming conditions based on the received elapsed wait time information. That is, if the elapsed wait time is longer than a fixed time, it is possible to shorten the wait time until start of the second programming counted in the timer circuit 420 once completion of the first programming is decided under the first programming verify during the elapsed wait time.

As described above, in this embodiment, surrounding charge that may deteriorate the data retention characteristic is reduced during the elapsed wait time from the time of the last second programming until the erasing operation before the first programming operation by utilizing the charge loss phenomenon caused by the binding between injected charge and the surrounding charge over a long time after the charge injection. If sufficient reduction of the surrounding charge over a long time is ensured, the next wait time after completion of the first programming until the second programming can be shortened. In actual use, data is often retained over a long time. Therefore, both improvement of the data retention characteristic and the shortening of the programming time can be attained.

### Embodiment 6

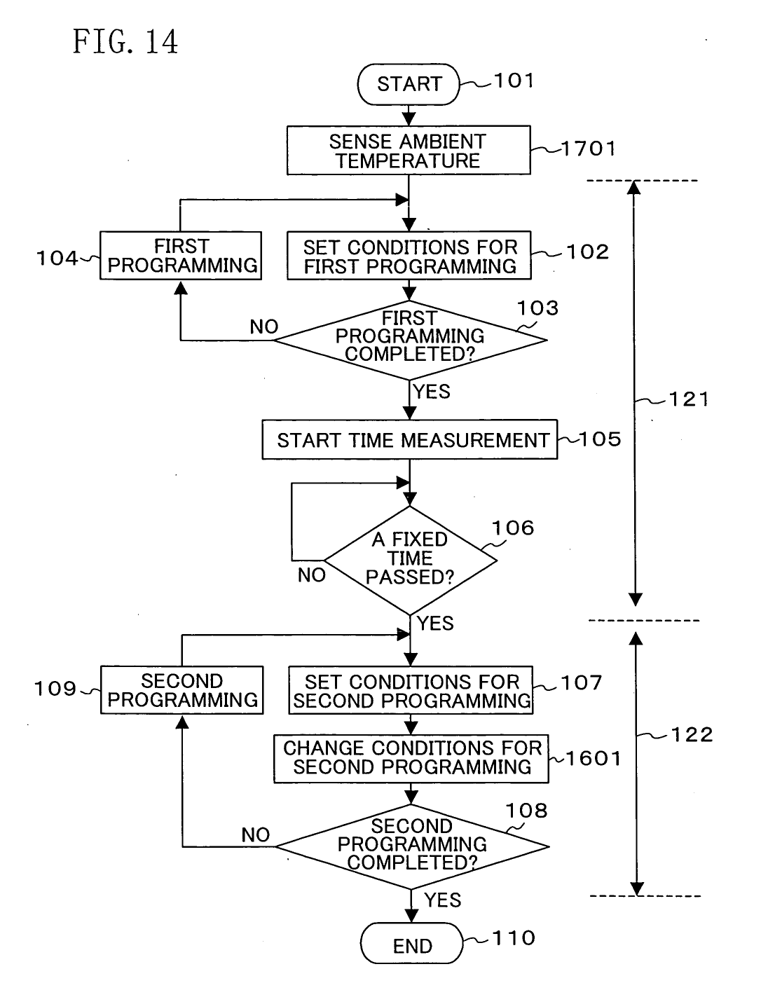

FIG. 14 is a flowchart showing a programming or erasing method for a nonvolatile semiconductor memory device in Embodiment 6 of the present invention. In the flowchart of FIG. 14, block 1701 represents processing of sensing the ambient temperature.

The programming flow for a given memory cell, starting at the start 101, proceeds to the processing 102 of setting desired first programming conditions via the processing 1701 of sensing the ambient temperature. The processing 1701 includes, for example, sensing the ambient temperature by monitoring the current amount flowing through a resistance.

After the processing 107 of setting conditions for executing the second programming, the flow proceeds to the processing 1601 of changing the conditions for executing the second programming. The processing 107 includes, for example, setting the voltage condition, the pulse width condition and the like for programming. The processing 1601 includes, for example, changing the voltage condition for the second programming to low setting if the ambient temperature is low. When the ambient temperature is low, the binding between electrons and holes will not be accelerated with temperature, and thus the charge loss in the initial variation after the first programming will be small. It is therefore unnecessary to execute the second programming at high voltage, and thus application of excessive stress can be avoided. On the contrary, if the ambient temperature is high, the voltage condition for the second programming is changed to high setting. When the ambient temperature is high, the binding between electrons and holes will be accelerated with temperature, and thus the charge loss in the initial variation after the first programming will be large. To compensate this, the voltage condition for the second programming is set at high voltage, to improve the data retention characteristic.

After the processing 1601, the flow proceeds to the decision 108 on whether or not the second programming has been completed. The decision 108 includes, for example, checking whether or not the programming pulse has been applied a predetermined number of times.

The wait time may be changed depending on the degree of the ambient temperature during the data programming. Otherwise, only the first charge injection may be executed depending on the degree of ambient temperature during the data programming.

### Embodiment 7

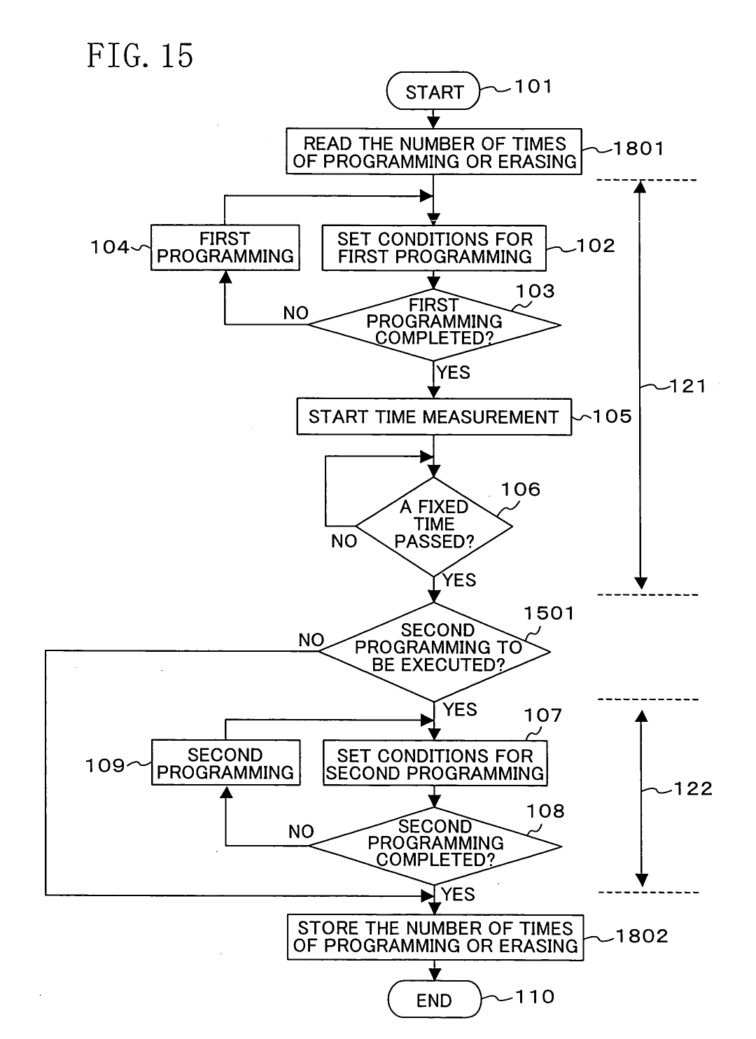

FIG. 15 is a flowchart showing a programming or erasing method for a nonvolatile semiconductor memory device in Embodiment 7 of the present invention. In the flowchart of FIG. 15, blocks 1801 and 1802 represent processing. The block 1801 represents processing of reading the number of times of programming or erasing, and 1802 represents processing of storing the number of times of programming or erasing.

The programming flow for a given memory cell, starting at the start 101, proceeds to the processing 102 of setting conditions for executing the first programming conditions via the processing 1801 of reading the number of times of programming or erasing executed so far. The processing 1801 includes, for example, reading information of the number of times of programming or erasing executed so far from a given area of a nonvolatile memory in which the information is stored.

In the decision 106, whether or not a fixed time has passed from the start of time measurement in the processing 105 is checked. If the fixed time has passed, the flow proceeds to the decision 1501. In the decision 1501, if the number of times of programming or erasing executed so far is small, the second programming is not executed and the flow proceeds to the processing 1802 of storing the number of times of programming or erasing. When the number of times of programming or erasing executed so far is small, the amount of surrounding charge that may deteriorate the data retention characteristic will be small, and thus the charge loss in the initial variation after the first programming will be small. No second programming is therefore necessary, and this can shorten the programming time. On the contrary, if the number of times of programming or erasing executed so far is large, the flow proceeds to the processing 107 of setting conditions for executing the second programming, to execute the second programming. When the number of times of programming or erasing executed so far is large, the amount of surrounding charge that may deteriorate the data retention characteristic will be large, and thus the charge loss in the initial variation after the first programming will be large. The second programming is therefore executed, to improve the data retention characteristic.

If it is decided in the decision 108 that the programming is completed, the flow proceeds to the processing 1802 of storing the number of times of programming or erasing and then to the end 110 to terminate the series of programming operations. The processing 1802 includes, for example, storing the number of times of programming or erasing at the time of termination of the programming in a given area of a nonvolatile memory. The stored information is used at the next programming or erasing.

The wait time may be changed depending on the number of times of programming or erasing. Otherwise, the conditions for the second charge injection may be changed depending on the number of times of programming or erasing.

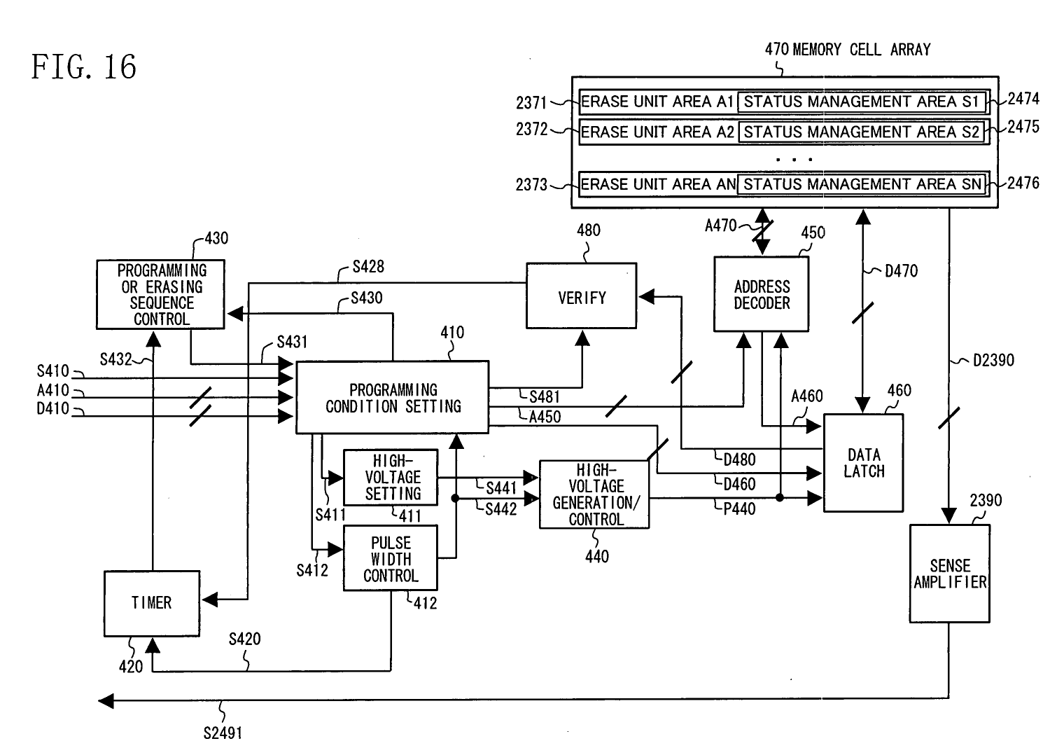

This embodiment can be implemented with the configuration of FIG. 16. FIG. 16 shows a nonvolatile semiconductor memory device in Embodiment 7 of the present invention. The configuration of FIG. 16 is the same as that of FIG. 5 except for the following points. The memory cell array 470 is divided into erase unit areas A(1) 2371 to A(N) 2373, which respectively include status management areas S(1) 2474 to S(N) 2476. A sense amplifier circuit 2390 is newly provided, which is connected with the memory cell array 470 via a data bus D2390 and outputs a status signal S2491.

The operation in programming will be described. In the first programming operation for a given erase unit area A(1, 2, . . . , N), data in the corresponding status management area S(1, 2, . . . , N) is erased.

In the second programming operation for a given erase unit area A(1, 2, . . . , N), data is written in the corresponding status management area S(1, 2, . . . , N).

A method for checking the status written in a given status management area S(1, 2, . . . , N) is as follows. A given status management area S(1, 2, . . . , N) is selected with the address decoder circuit 450, and data in the selected status management area S(1, 2, . . . , N) is read with the sense amplifier circuit 2390 via the data bus D2390 and output as the status signal S2491. Thus, depending on whether the corresponding erase unit area A(1, 2, . . . , N) is in the erased state or the written state, it is possible to determine whether or not the programming of each unit area has been completed up to the second programming.

In the status management area S(1, 2, . . . , N), data indicating the number of times of programming or erasing for the corresponding erase unit area may be written. In this case, the wait time from completion of the first programming until the second programming may be shortened depending on the number of times of programming or erasing for each erase unit area.

As described above, with the configuration of FIG. 16 provided with the status management area for each erase unit area, it becomes easy to determine whether each area is in the state after the first programming or the state after the second programming, and this improves the controllability. In the case of writing the number of times of programming or erasing for each erase unit area in the corresponding status management area, the wait time from completion of the first programming until the second programming can be shortened depending on the number of times of programming or erasing for each erase unit area.

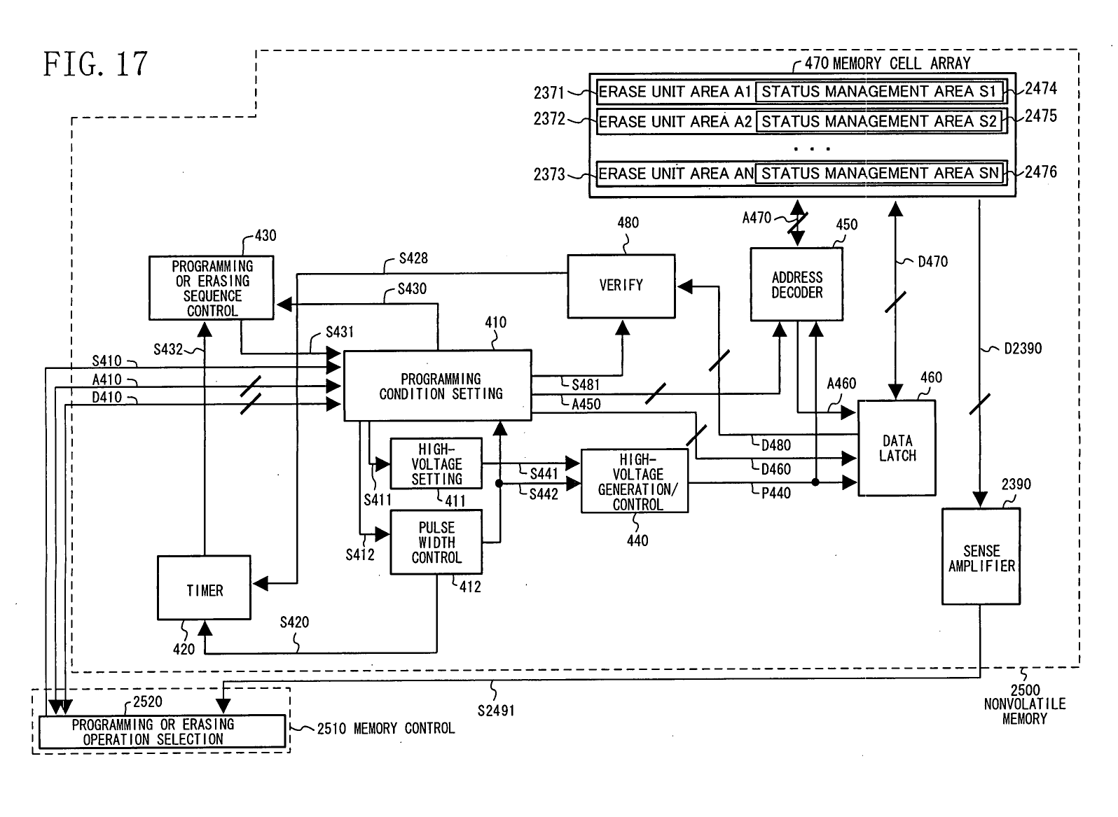

FIG. 17 shows electronic equipment using the nonvolatile semiconductor memory device (nonvolatile memory 2500) of FIG. 16. The electronic equipment includes the nonvolatile memory 2500 having the same configuration as the device of FIG. 16 and a memory control circuit 2510 electrically connected to the nonvolatile memory 2500. The memory control circuit 2510 includes a programming or erasing operation selection circuit 2520 that receives the status signal S2491 and is in connection with the control signal S410, the address bus A410 and the data bus D410.

As described above with reference to FIG. 16, in the first programming operation for a given erase unit area A(1, 2, . . . , N), data in the corresponding status management area S(1, 2, . . . , N) is erased. In the second programming operation for a given erase unit area A(1, 2, . . . , N), data is written in the corresponding status management area S(1, 2, . . . , . . . . N). By checking the status written in the status management area S(1, 2, . . . , N) under the reading operation, it is possible to determine whether or not the programming of each erase unit area has been completed up to the second programming depending on whether the corresponding erase unit area A(1, 2, . . . , N) is in the erased state or the written state. To execute the above operations, the nonvolatile memory 2500 receives the control signal S410 for controls required for the first programming operation, the second programming operation and the read operation, receives the address signal via the address bus A410, and receives/outputs data via the data bus D410, from/to the programming or erasing operation selection circuit 2520. Also, in the case of writing the number of times of programming or erasing for each erase unit area in the corresponding status management area S(1, 2 . . . . N), the number of times of programming or erasing for each erase unit area A(1, 2 . . . . N) is input into the programming or erasing operation selection circuit 2520 as the status signal S2491. Accordingly, depending on the number of times of programming or erasing for each erase unit area, the wait time after completion of the first programming until the second programming can be shortened. Alternatively, depending on the use, execution or not of the second programming operation after completion of the first programming is made selectable for each erase unit area.

As described above, with the configuration of FIG. 17, the length of the wait time after the first programming and execution or not of the second programming is made selectable depending on the number of times of programming or erasing for each erase unit area and also depending on the use in the market. Therefore, electronic equipment capable of optimally improving the reliability and reducing the programming time can be implemented.

### Embodiment 8

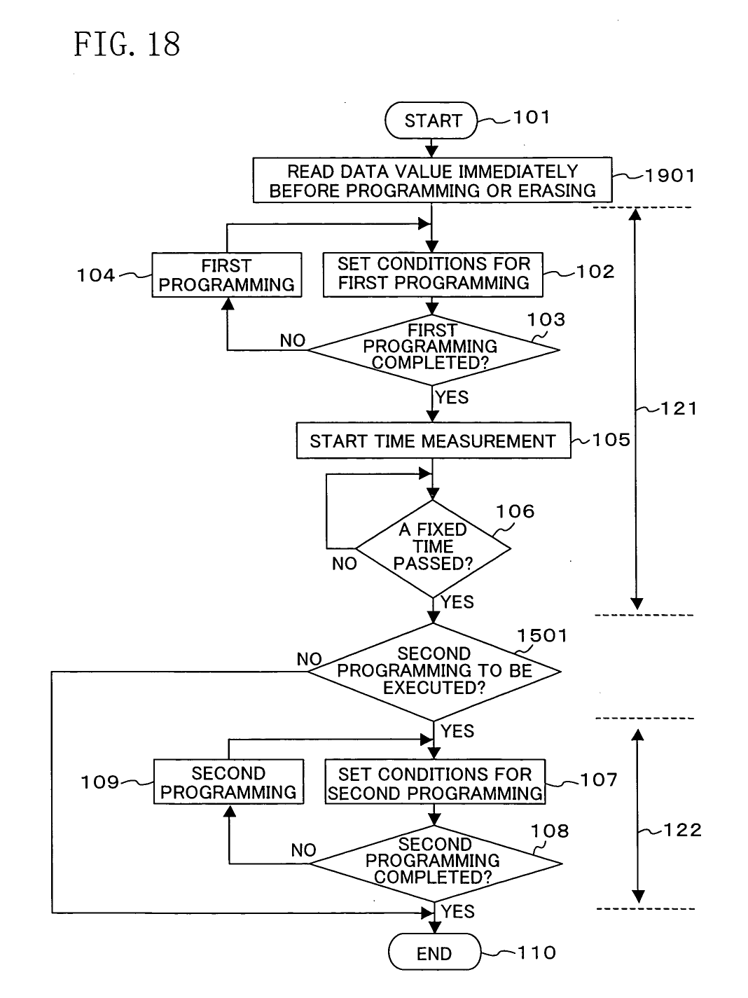

FIG. 18 is a flowchart showing a programming or erasing method for a nonvolatile semiconductor memory device in Embodiment 8 of the present invention. In the flowchart of FIG. 18, block 1901 represents processing of reading the data value immediately before programming or erasing.

The programming flow for a given memory cell, starting at the start 101, proceeds to the processing 102 of setting desired first programming conditions via the processing 1901 of reading the data value immediately before the programming or erasing. The processing 1901 is, for example, read verify for determining whether data “0” or data 1”.

In the decision 106, whether or not a fixed time has passed from the start of time measurement in the processing 105 is checked. If the fixed time has passed, the flow proceeds to the decision 1501. In the decision 1501, if the data immediately before the programming or erasing is “0”, the second programming is not executed, and the flow proceeds to the end 110 to terminate the programming flow. When the data immediately before the programming or erasing is “0”, the binding between electrons and holes must have been made sufficiently, and thus the charge loss in the initial variation after the first programming must be small. No second programming is therefore necessary, and this can shorten the programming time. On the contrary, if the data immediately before the programming or erasing is “1”, the flow proceeds to the processing 107 of setting conditions for executing the second programming, to execute the second programming. When the data immediately before the programming or erasing is “1”, the binding between electrons and holes must be insufficient, and thus the charge loss in the initial variation after the first programming must be large. The second programming is therefore executed, to improve the data retention characteristic.

The wait time may be changed depending on the data value immediately before the programming or erasing. Otherwise, the charge injection conditions for the second charge injection may be changed depending on the data value immediately before the programming or erasing.

### Embodiment 9

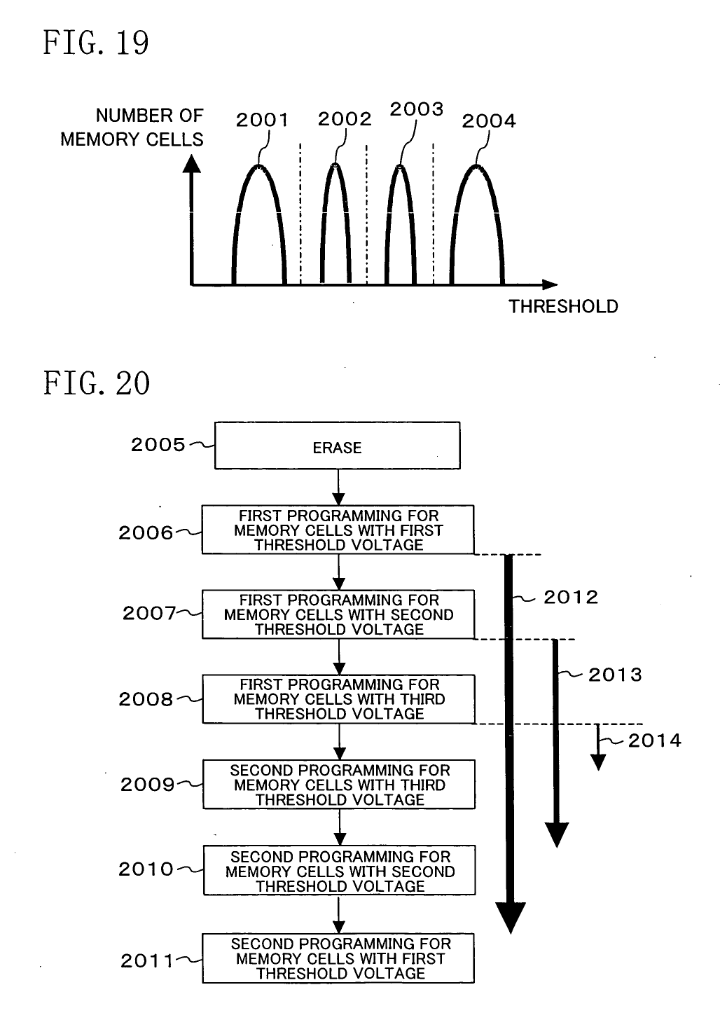

FIG. 19 shows the relationships between the threshold and the number of memory cells in 4-valued memory cells. In FIG. 19, the reference numerals 2001 through 2004 respectively denote the relationships for memory cells in the erased state, memory cells in the programmed state under a first threshold voltage, memory cells in the programmed state under a second threshold voltage, and memory cells in the programmed state under a third threshold voltage. The threshold is higher in the order of the erased state, the first threshold voltage, the second threshold voltage and the third threshold voltage.

FIG. 20 is a view showing a programming or erasing method for a nonvolatile memory device in Embodiment 9 of the present invention. Block 2005 represents processing of executing erase. Blocks 2006 through 2008 represents processing of executing the first programming for memory cells with the first threshold voltage, memory cells with the second threshold voltage and memory cells with the third threshold voltage, respectively. Blocks 2009 through 2011 represents processing of executing the second programming for the memory cells with the third threshold voltage, the memory cells with the second threshold voltage and the memory cells with the first threshold voltage, respectively. Block 2012 through 2014 represent the wait times after the first programming for the memory cells with the first threshold voltage, the memory cells with the second threshold voltage and the memory cells with the third threshold voltage, respectively.

The programming flow for a given memory cell starts at the processing 2005 of executing erase, and proceeds to the processing 2006 of executing the first programming for the memory cells with the first threshold voltage, then to the processing 2007 of executing the first programming for memory cells with the second threshold voltage and to the processing 2008 of executing the first programming for memory cells with the third threshold voltage. The processing 2005 is erase before data programming or erasing, the processing 2006 is the first programming for memory cells for which a low threshold voltage is set, the processing 2007 is the first programming for memory cells for which a higher threshold voltage is set, and the processing 2008 is the first programming for memory cells for which a further higher threshold voltage is set.

The process then proceeds from the processing 2008 to the processing 2009 of executing the second programming for the memory cells with the third threshold voltage, then to the processing 2010 of executing the second programming for memory cells with the second threshold voltage and to the processing 2011 of executing the second programming for memory cells with the first threshold voltage. The processing 2009 is the second programming for the memory cells for which a high threshold voltage is set, the processing 2010 is the second programming for the memory cells for which a lower threshold voltage is set, and the processing 2011 is the second programming for the memory cells for which a further lower threshold voltage is set.

The time difference between the processing 2006 and the processing 2011 corresponds to the wait time 2012 after the first programming for the memory cells with the first threshold voltage. Likewise, the time difference between the processing 2007 and the processing 2010 corresponds to the wait time 2013 after the first programming for the memory cells with the second threshold voltage, and the time difference between the processing 2008 and the processing 2009 corresponds to the wait time 2014 after the first programming for the memory cells with the third threshold voltage.

To ensure roughly the same effect of the data retention characteristic for all the memory cells, a longer wait time must be secured for memory cells for which a low threshold voltage is set than for memory cells for which a high threshold voltage is set. According to the method described above, by utilizing the programming time for memory cells for which a high threshold voltage is set, the increase in programming or erasing time that may occur by implementing the present invention can be reduced.

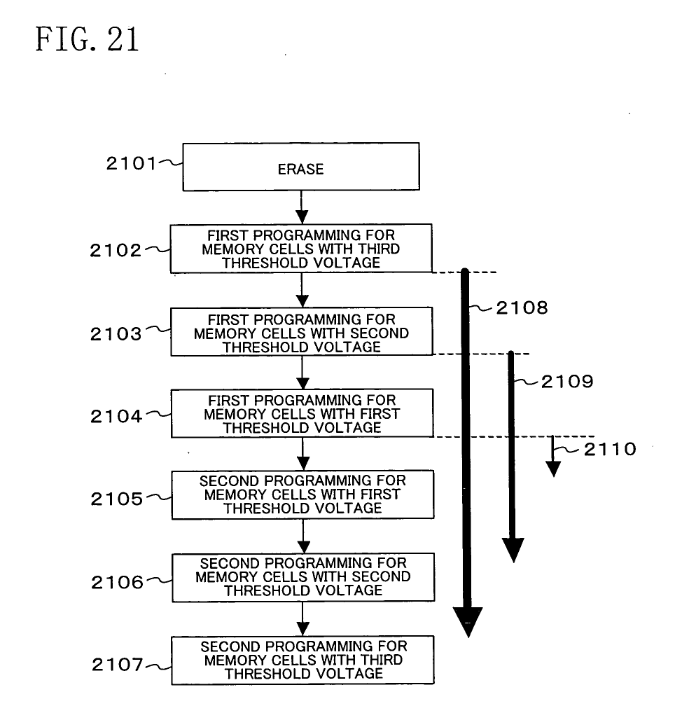

FIG. 21 shows an alternative method in Embodiment 9, in which the order of the first to third threshold voltages set for memory cells to be programmed is reverse to that in FIG. 20.

In the method shown in FIG. 21, as the set threshold voltage is higher, a longer wait time is secured. This makes it possible to improve the data retention characteristic of memory cells high in threshold voltage that are large in charge loss in the initial variation. Also, by utilizing the programming time for memory cells for which a low threshold voltage is set, the increase in programming or erasing time that may occur by implementing the present invention can be reduced.

### Embodiment 10

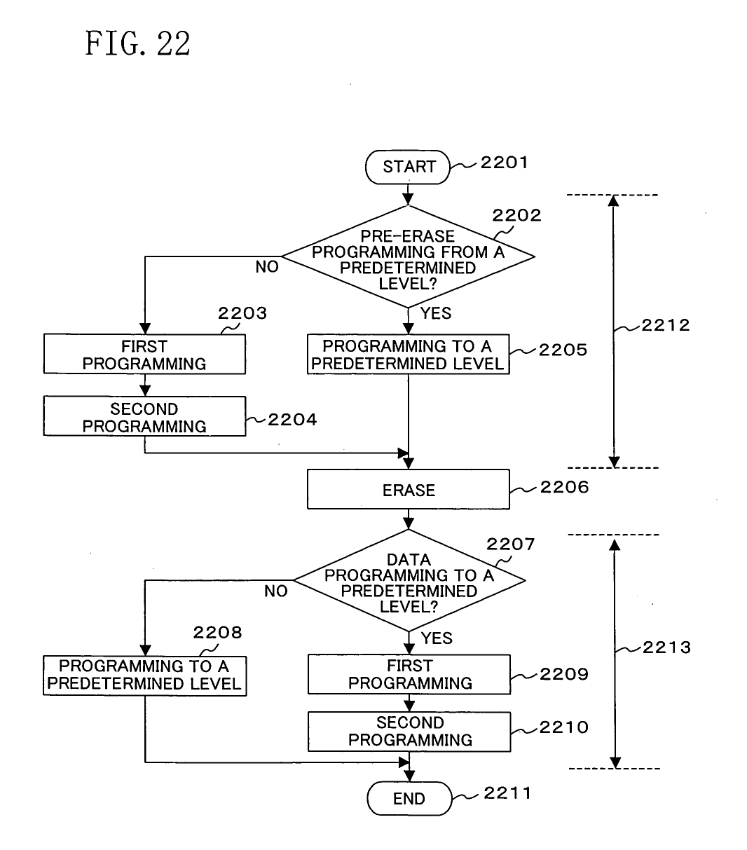

FIG. 22 is a flowchart showing a programming or erasing method for a nonvolatile semiconductor memory device in Embodiment 10 of the present invention. In the flowchart of FIG. 22, blocks 2201 and 2211 respectively represent the start and the end, 2203 to 2206 and 2208 to 2210 represent processing, and 2202 and 2207 represent decision. The reference numerals 2212 and 2213 represent ranges.

The range 2212 covers pre-erase programming, and the range 2213 covers data programming. The block 2202 represents decision on whether or not the current programming is pre-erase programming from a predetermined threshold voltage level, executed at the start of the pre-erase programming, and 2207 represents decision on whether or not the current programming is data programming to a predetermined threshold voltage level. The blocks 2203 and 2209 represent processing of executing the first programming, 2204 and 2210 represent processing of executing the second programming, 2205 and 2208 represent processing of executing programming to a predetermined level, and 2206 represents processing of executing erase.

A programming or erasing method for a multi-valued nonvolatile memory in which data is stored with three or more threshold voltage values, as shown in FIG. 19, will be described. The flow starting at the start 2201 proceeds to the decision 2202 on whether or not the current programming is pre-erase programming from a predetermined level. The predetermined level herein refers to the highest level of the threshold voltage, like the voltage distribution 2004 for memory cells in the programmed state under the third threshold voltage shown in FIG. 19, for example. If the pre-erase programming is from the predetermined level, the flow proceeds to the processing 2205 of executing programming to a predetermined level. Otherwise, the flow proceeds to the first programming 2203 and then to the second programming 2204. The programming to a predetermined level herein refers to programming to a pre-erase programming level. In the case that the pre-erase programming level is roughly equal to the highest level of the threshold voltage, the processing 2205 of programming to a predetermined level may be omitted. The second programming 2204 to be executed if the current processing is not pre-erase processing from a predetermined level may be omitted because, as described n Embodiment 2, it is unnecessary to raise the level reduced with the binding between electrons and holes.

Once the pre-erase programming 2212 is completed, the flow proceeds to the erase 2206 and then to the decision 2207 on whether or not the current programming is data programming to a predetermined level in the data programming 2213. The predetermined level herein is basically the same as the level used in the decision 2202 in the pre-erase programming, that is, the highest level of the threshold voltage, like the voltage distribution 2004 for memory cells in the programmed state under the third threshold voltage shown in FIG. 19, for example. If the current programming is data programming to a predetermined level, the flow proceeds to the first programming 2209 and then to the second programming 2210. Otherwise, the flow proceeds to processing 2208 of executing programming to a predetermined level. Once the data programming 2213 is terminated, the flow terminates at the end 2211.

In the programming or erasing method in this embodiment, the present invention is applied in either the pre-erase programming or the data programming depending on the level among the multi-valued threshold voltage levels. For example, for memory cells for which a low threshold voltage level is set, the present invention is not applied in the data programming because the effect obtained by applying the present invention will be small compared with the time required for this application, but is applied only in the pre-erase programming. In reverse, for memory cells for which a high threshold voltage level is set, the present invention is applied in the data programming because characteristics may be improved during the data retention time period by applying the present invention, but is not applied in the pre-erase programming because the effect itself is small. In this way, a roughly equal effect can be provided for all multi-valued memory cells for which various threshold levels are set. Thus, in a multi-valued memory, also, improvement in charge retention characteristic and improvement in the number of times of programming or erasing can be attained while the increase of the programming or erasing time is minimized.

In application of the present invention to memory cells for which a further high threshold voltage level is set, the method shown in FIG. 21 may be adopted, in which the first programming is first executed for memory cells for which a high threshold voltage level is set, and during the wait time belonging to the first programming, memory cells for which a low threshold voltage level is set are programmed. By adopting this method, more efficient improvement of the data retention characteristic can be attained while the increase of the programming or erasing time is minimized.

As described above, the memory devices according to the present invention are useful as nonvolatile memories having a trap layer that can improve the data retention characteristic of memory cell, and the like.

While the present invention has been described in preferred embodiments, it will be apparent to those skilled in the art that the disclosed invention may be modified in numerous ways and may assume many embodiments other than that specifically set out and described above. Accordingly, it is intended by the appended claims to cover all modifications of the invention which fall within the true spirit and scope of the invention.

What is claimed is:

1. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage, and
in the second charge injection step, charge injection is executed up to a given threshold voltage only when a given determination level has been reached.

2. The method of claim 1, wherein the second charge injection step is repeated a given number of times.

3. A programming or erasing method for a nonvolatile semiconductor memory device having a top layer, the method comprising, in pre-erase programming, a first charge injection step and a second charge injection step executed after the first charge injection step,
wherein in the first charge injection step, a given wait time is secured after charge injection is executed up to a given threshold voltage, and
in the second charge injection step, charge injection is executed up to a given threshold voltage.

4. The method of claim 3, wherein, in data programming, the first charge injection and the second charge injection are executed under conditions changed from conditions for the pre-erase programming.

5. The method of claim 4, wherein only the first charge injection step is executed in the pre-erase programming.

6. The method of claim 3, wherein, in the first charge injection step in the pre-erase programming, the charge injection is executed up to a programming level above a level adopted in the data programming.

7. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
conditions of the first charge injection and the second charge injection are changed with a production unit.

8. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
conditions of the first charge injection and the second charge injection are changed with a programming or erasing unit.

9. A programming or erasing method For a nonvolatile semiconductor memory vice having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
conditions of the first charge injection and the second charge injection are set for each production unit in a testing process.

10. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
conditions of the first charge injection and the second charge injection are set for each programming or erasing unit in a testing process.

11. A programming or erasing method for a nonvolatile semiconductor memory device having a top layer, the method comprising, in programming or erasing, a first charge injection step and a second charge injection step executed after the first charge injection
wherein in the first charge injection step, a given wait time is secured after charge injection is executed up to a given threshold voltage,
in the second charge injection step, charge injection is executed up to a given threshold voltage, and
conditions of the first charge injection and the second charge injection are set for each programming or erasing unit according to a characteristic in preceding programming or erasing.

12. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
the wait time changes with the length of a left-to-stand time from last data programming until the programming or erasing.

13. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
only the first charge injection step may be executed depending on the length of a left-to-stand time from last data programming until the programming or erasing.

14. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection conditions in the second charge injection step changes with the length of a left-to-stand time from last data programming until the programming or erasing.

15. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
wait time changes with the degree of the ambient temperature during data programming.

16. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
only the first charge injection step may be executed depending on the degree of the ambient temperature during data programming.

17. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection conditions in the second charge injection step changes with the degree of the ambient temperature in data programming.

18. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
the wait time changes with the number of times of data programming or erasing.

19. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
only the first charge injection step may be executed depending on the number of times of programming or erasing.

20. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection conditions in the second charge injection step changes with the number of times of data programming or erasing.

21. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
the wait time changes with a data value immediately before the programming or erasing.

22. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
only the first charge injection step may be executed depending on a data value immediately before the programming or erasing.

23. A programming or erasing method for a nonvolatile semiconductor memory device having a top layer, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection conditions in the second charge injection step changes with a data value immediately before the programming or erasing.

24. A programming or erasing method for a nonvolatile semiconductor memory device having a top layer and three or more memory cell threshold voltage values, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection is first executed for memory cells for which a low threshold voltage is set, then charge injection is executed for memory cells for which a higher threshold voltage is set while a wait time after the first charge injection for the memory cells for which a low threshold voltage is set is secured, and thereafter the second charge injection is executed for the memory cells for which a low threshold voltage is set.

25. A programming or erasing method for a nonvolatile semiconductor memory device having a top layer and three or more memory cell threshold voltage values, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
charge injection is first executed for memory cells for which a high threshold voltage is set, then charge injection is executed for memory cells for which a lower threshold voltage is set while a wait time after the first charge injection for the memory cells for which a high threshold voltage is set is secured, and thereafter the second charge injection is executed for the memory cells for which a high threshold voltage is set.

26. A programming or erasing method for a nonvolatile semiconductor memory device having a top layer and three or more memory cell threshold voltage values, the method comprising, in programming or erasing, a first charge injection step and a second charge injection step executed after the first charge injection step,
wherein in the first charge injection step, a given wait time is secured after charge injection is executed up to a given threshold voltage,
in the second charge injection step, charge injection is executed up to a given threshold voltage, and
whether or not the first charge injection and the second charge injection should be executed in data programming, or both the first charge injection and the second charge injection or only the first charge injection should be executed in pre-erase programming is determined according to the memory cell threshold voltage level.

27. The method of claim 26, wherein in programming or erasing, in particular, the first charge injection is executed in the pre-erase programming for memory cells for which a low threshold voltage is set before the programming or erasing, and in the data programming after erasing, first, the first charge injection and the second charge injection are executed for memory cells for which a high threshold voltage is set, the wait time after the first charge injection is secured using a programming time for memory cells for which a lower threshold voltage is set, and thereafter the second charge injection is executed for the memory cells for which a high threshold voltage is set.

28. A nonvolatile semiconductor memory device comprising:
a nonvolatile memory array having a trap layer;
a programming or erasing sequence control circuit for controlling a given wait time after execution of charge injection up to a given memory cell threshold voltage in first charge injection and then controlling second charge injection after the given wait time so that the first charge injection and the second charge injection are executed in programming or erasing; and
a time management area, provided for each erase unit area of the nonvolatile memory array, for storing a time at which the first charge injection was executed.

29. A nonvolatile semiconductor memory device comprising:
a nonvolatile memory array having a trap layer;
a programming or erasing sequence control circuit for controlling a given wait time after execution of charge injection up to a given memory cell threshold voltage in first charge injection and then controlling second charge injection after the given wait time so that the first charge injection and the second charge injection are executed in programming or erasing; and
a status management area, provided for each erase unit area of the nonvolatile memory array, for storing a status of being after the first charge injection or after the second charge injection.

30. Electronic equipment comprising:
a nonvolatile semiconductor memory device having a trap layer, comprising a programming or erasing sequence control circuit for controlling a given wait time after execution of charge injection up to a given memory cell threshold voltage in first charge injection and then controlling second charge injection after the given wait time so that the first charge injection and the second charge injection are executed in programming or erasing; and
a programming or erasing operation selection circuit capable of switching between the first charge injection and the second charge injection after termination of the control of the given wait time in the first charge injection.
